(19) United States
(12) Patent Application Publication
(10) Pub. No.: US 2026/0251582 A1
(43) Pub. Date: Aug. 27, 2026

(54) OPTICAL FOREIGN MATTER INSPECTION DEVICE AND PROGRAM

(71) Applicant: Hitachi High-Tech Corporation, Minato-ku, Tokyo (JP)

(72) Inventors: Takayasu IWATSUKA, Tokyo (JP); Tomoharu NAGASHIMA, Tokyo (JP); Hisaaki KANAI, Tokyo (JP)

(21) Appl. No.: 19/160,233

(22) PCT Filed: Jul. 14, 2023
(86) PCT No.: PCT/JP2023/026094

§ 371 Date: Aug. 27, 2025

(51) Int. Cl. G01N 21/94; G01N 21/47; G01N 21/95; H10P 72/76

(52) U.S. Cl. CPC G01N 21/94; G01N 21/4788; G01N 21/9501; H10P 72/7618; G01N 2201/021; G01N 2201/06113; G01N 2201/103

(57) ABSTRACT

An optical foreign matter inspection device capable of realizing high accuracy in specifying a foreign matter position in a wide rotational speed range of a rotary stage, including a first head and a second head each detecting the graduations of an annular scale provided on the rotary stage and outputting a signal. A rotational speed range of the rotary stage which can be supported by the first head and a rotational speed range of the rotary stage which can be supported by the second head partially overlap and are relatively different. A calculation control circuit included in the optical foreign matter inspection device determines a head to be used to be either the first head or the second head, based on the rotational speed of the rotary stage, and determines the rotation angle of the rotary stage based on the signal from the head to be used.

### TECHNICAL FIELD

The present invention relates to an optical foreign matter inspection device and a program therefor.

### BACKGROUND ART

An optical foreign matter inspection device is a device which detects foreign matter on a sample such as a semiconductor wafer made of silicon, gallium arsenide, etc. The optical foreign matter inspection device has a rotary stage and a translation stage which straightly advances the rotary stage in the radial direction, and detects the foreign matter on the sample by irradiating the sample with laser light while rotating and translating the rotary stage on which the sample is placed, and monitoring the intensity of scattered light from the surface of the sample. The position of the foreign matter is generally specified by reading the scales of a rotary encoder attached to the rotary stage and a linear encoder attached to the translation stage. Patent Literature 1 describes the optical foreign matter inspection device configured as described above.

### CITATION LIST

### Patent Literature

Patent Literature 1: WO2021/070265

### SUMMARY OF INVENTION

### Technical Problem

In recent years, there has been a demand for an optical foreign matter inspection device to achieve both high sensitivity inspection and high throughput inspection. In order to meet this demand, there is a need to expand a rotational speed range which can be supported by a rotary stage.

On the other hand, the rotational speed range of the rotary stage at which the scale of the rotary encoder can be read with high accuracy is determined by the specifications of each rotary encoder. The required rotational speed range is wider than the rotational speed range determined by the specifications. That is, it is desirable to realize high accuracy in specifying a foreign matter position over a wider range of rotational speeds of the rotary stage in an optical foreign matter inspection device, but there is still room for improvement to realize it.

An object of the present invention is to realize high accuracy in specifying a foreign matter position over a wider range of rotational speeds of a rotary stage in an optical foreign matter inspection device.

### Solution to Problem

An aspect of the present invention is an optical foreign matter inspection device which detects foreign matter on a surface of a sample, and includes: a rotary stage on which the sample is placed; a motor which rotates the rotary stage; a base to which the motor is fixed; an annular scale provided on the rotary stage; a first head and a second head which are installed on the base and which detect the graduations of the scale and output a signal; a laser light source which irradiates laser light toward the surface of the sample; an optical sensor which receives scattered or reflected light of the laser light from the surface of the sample and outputs a signal according to the intensity of the received light; and a calculation control circuit which performs processing of controlling the motor and processing of specifying a position of the foreign matter on the sample based on a signal from the first head or the second head and a signal from the optical sensor. A rotational speed range of the rotary stage capable of being supported by the first head and a rotational speed range of the rotary stage capable of being supported by the second head are relatively different from each other so as to overlap partially, and the calculation control circuit determines, based on the rotational speed of the rotary stage, either of the first head and the second head as a head to be used for specifying a rotation angle of the rotary stage, and determines a rotation angle of the rotary stage based on a signal from the used head.

An aspect of the present invention is an optical foreign matter inspection device which detects foreign matter on a surface of a sample, and includes: a rotary stage on which the sample is placed; a motor which rotates the rotary stage; a base to which the motor is fixed; an annular scale provided on the rotary stage; a stage unit including a head which is installed on the base and which detects the graduations of the scale and outputs a signal; a laser light source which irradiates laser light toward the surface of the sample; an optical sensor which receives scattered or reflected light of the laser light from the surface of the sample and outputs a signal according to the intensity of the received light; and a calculation control circuit which performs processing of controlling the motor and processing of specifying a position of the foreign matter on the sample based on the signal from the head and the signal from the optical sensor. The calculation control circuit stores rotation angle correction information for the head, the rotation angle correction information for the head has a characteristic which changes when an installation rotation angle of the head changes, and the calculation control circuit specifies a rotation angle of the rotary stage based on the signal from the head, and corrects the specified rotation angle using the rotation angle correction information for the head.

An aspect of the present invention is a program for use in an optical foreign matter inspection device including: a rotary stage on which a sample is placed; a motor which rotates the rotary stage; a base to which the motor is fixed; an annular scale provided on the rotary stage; a first head and a second head which are installed on the base and which detect graduations of the scale and output a signal; a laser light source which irradiates laser light toward a surface of the sample; an optical sensor which receives scattered or reflected light from the surface of the sample and outputs a signal according to the intensity of the received light; and a calculation control circuit including a processor, in which a rotational speed range of the rotary stage supportable by the first head and a rotational speed range of the rotary stage supportable by the second head are relatively different from each other so as to partially overlap, and the program causes the processor to execute: processing of controlling the motor, processing of specifying a position of foreign matter on the sample based on the signal from the first head or the second head and the signal from the optical sensor, processing of determining, based on a rotational speed of the rotary stage, either of the first head and the second head as a head to be used for specifying the rotation angle of the rotary stage, and processing of determining a rotation angle of the rotary stage based on the signal from the head to be used.

### Advantageous Effects of Invention

According to an aspect of the present invention, it is possible to realize high accuracy in specifying a foreign matter position over a wider range of rotational speeds of a rotary stage in an optical foreign matter inspection device.

### BRIEF DESCRIPTION OF DRAWINGS

FIG. 1 is a diagram showing an example of a configuration of an optical foreign matter inspection device according to a first embodiment.

FIG. 2 is a diagram showing an example of a hardware configuration of a semiconductor circuit device in the first embodiment.

FIG. 3 is a diagram schematically showing a portion which functions as a rotary encoder of the optical foreign matter inspection device according to the first embodiment.

FIG. 4 is a diagram showing a temporal change in the rotational speed of a rotary stage during the inspection in the first embodiment and a supportable rotational speed range of a head.

FIG. 5 is a flowchart showing an example of a flow of processing in the optical foreign matter inspection device according to the first embodiment.

FIG. 6 is a diagram showing an example of a configuration of an optical foreign matter inspection device according to a second embodiment.

FIG. 7 is a diagram for describing that a detection rotation angle of a foreign matter on a wafer differs between an ideal rotary encoder and a real rotary encoder in the second embodiment.

FIG. 8 is a diagram showing an example of a change in a rotation angle based on the pulse count number of an encoder with respect to a true rotation angle in the second embodiment.

FIG. 9 is a diagram showing a concept of correction information of an encoder in the second embodiment and an example thereof.

FIG. 10 is a flowchart showing an example of a flow of processing in the optical foreign matter inspection device 2 according to the second embodiment.

FIG. 11 is a diagram showing an example of a configuration of an optical foreign matter inspection device according to a third embodiment.

FIG. 12 is a flowchart showing an example of a flow of processing by a first generation method of encoder correction information in the optical foreign matter inspection device according to the third embodiment.

FIG. 13 is a diagram for describing the first generation method of the correction information according to the third embodiment in detail.

FIG. 14 is a flowchart showing an example of a flow of processing by a second generation method of encoder correction information in an optical foreign matter inspection device according to a fourth embodiment.

FIG. 15 is a diagram for describing a calculation method of angular velocity and angular acceleration in the fourth embodiment.

FIG. 16 is a diagram for describing a flow of calculation of correction information in the fourth embodiment.

FIG. 17 is a diagram showing an example of a graph obtained by plotting a rotation angle correction amount with respect to a rotation angle based on the pulse count number of an encoder according to a fifth embodiment.

FIG. 18 is a diagram for describing a method of state diagnosis of an encoder according to a sixth embodiment.

FIG. 19 is a diagram showing an example of a configuration of a management system according to a seventh embodiment.

FIG. 20 is an example of an image of a GUI displaying monitor results of a plurality of optical foreign matter inspection devices according to a seventh embodiment.

FIG. 21 is a flowchart showing an example of a flow of processing in an optical foreign matter inspection device according to an eighth embodiment.

### DESCRIPTION OF EMBODIMENTS

Hereinafter, embodiments will be described in detail with reference to the drawings. In the drawings, the same elements are indicated by the same reference numerals, and the overlapped description thereof is omitted. In the case where there are a plurality of same or similar elements, description may be given by attaching different suffixes to the same sign. In the drawings, the representation of each component may not represent an actual position, size, shape, range, and the like to facilitate the understanding of the invention, and the present invention is not necessarily limited to the position, size, shape, range and the like disclosed in the drawings. Expressions such as identification information, identifiers, IDs, names, numbers, and the like for various types of data and information can be replaced with each other.

Although a functional block, a circuit, a computer, a processing unit, and the like constituting a device or a system may be implemented in an electronic circuit combining electronic components, or the like, a processor or a semiconductor device such as a computer including a processor may be implemented by executing a predetermined program.

The processor is comprised of, for example, a semiconductor device such as a CPU (Central Processing Unit), a GPU (Graphics Processing Unit), an MCU (Micro Controller Unit), and the like. The processor is comprised of a device and a circuit capable of performing a predetermined arithmetic operation. Processing is not limited to software program processing and can also be executed by a dedicated circuit. The dedicated circuit is applicable to an FPGA (Field Programmable Gate Array), an ASIC (Application Specific Integrated Circuit), and the like.

The program may be installed in advance in a target computer as data, or may be distributed and installed as data from a program source to the target computer. The program source may be a program distribution server on a communication network or may be a non-transitory computer-readable storage medium. The program may be comprised of a plurality of program modules. A computer system may be comprised of a plurality of devices.

### First Embodiment

A first embodiment of the present invention provides an optical foreign matter inspection device in which a rotational speed range of a rotary stage which can correspond to a function of specifying a rotation angle position of the rotary stage is enlarged. The optical foreign matter inspection device according to the first embodiment includes, as a head for reading graduations of an annular scale provided on the rotary stage, a first head having a relatively high rotational speed range capable of reading, and a second head having a relatively low rotational speed range capable of reading. The optical foreign matter inspection device according to the first embodiment switches the head to be used, based on the rotational speed of the rotary stage.

### Configuration of Optical Foreign Matter Inspection Device According to First Embodiment

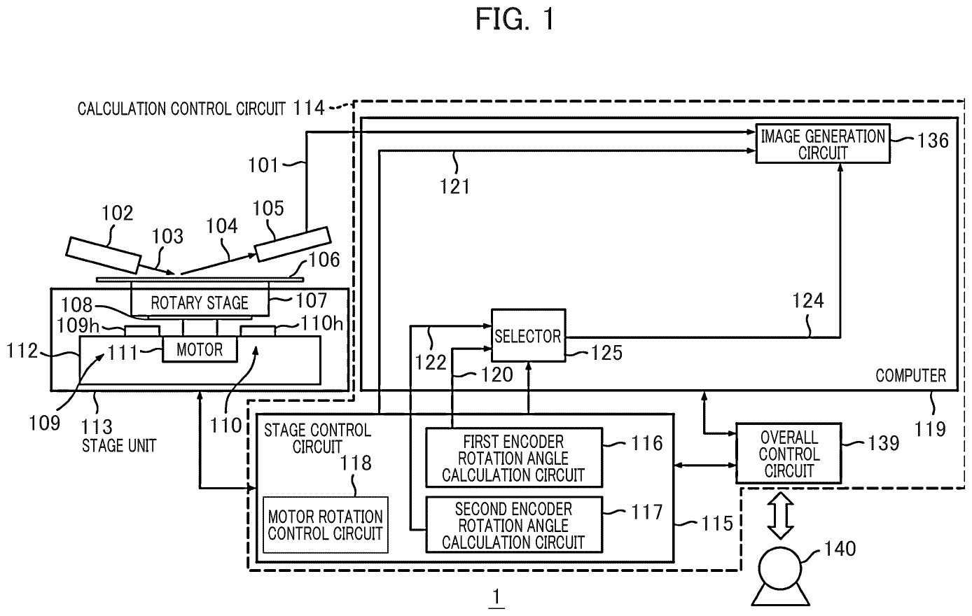

FIG. 1 is a diagram showing an example of a configuration of the optical foreign matter inspection device according to the first embodiment. As shown in FIG. 1, the optical foreign matter inspection device 1 according to the first embodiment includes a laser light source 102, an optical sensor 105, a stage unit 113, and a calculation control circuit 114. The stage unit 113 includes a rotary stage 107, a scale 108, a first head 109h, a second head 110h, a motor 111, and a base 112. The calculation control circuit 114 further includes a stage control circuit 115, a computer 119, and an overall control circuit 139.

The rotary stage 107 has a substantially disk shape, and is configured to be rotatable about a central axis of the rotary stage 107 as a rotation center axis. A sample to be inspected is placed and held on the surface of the rotary stage 107. Here, a wafer 106 is assumed as the sample. The wafer 106 is, for example, a semiconductor wafer comprised of a material such as silicon or gallium arsenide.

The rotary stage 107 is connected to a rotation shaft of the motor 111 and rotates in a horizontal plane by driving the motor 111. The motor 111 is supported and fixed by the base 112. The base 112 has a mechanism capable of linearly moving in the direction of the rotation radius of the rotary stage 107, and moves horizontally in a straight line when driven by an illustrated drive source. That is, the rotary stage 107 is configured to perform rotational translational motion.

The scale 108 is annular, and is provided on the back surface, i.e., the bottom surface of the rotary stage 107 so that the center of rotation of the rotary stage 107 and the geometric center of the scale 108 are at the same position except for mounting errors.

The first head 109h and the second head 110h are installed on the base 112. The combination of the scale 108 and the first head 109h constitutes a first encoder 109. Further, the combination of the scale 108 and the second head 110h constitutes a second encoder 110. That is, the scale 108 is shared by the first encoder 109 and the second encoder 110.

The first encoder 109 outputs a read signal at a timing when the first head 109h detects and reads the graduations of the scale 108. Similarly, the second encoder 110 outputs a read signal at a timing when the second head 110h detects and reads the graduations of the scale 108. The read signal of the first head 109h, i.e., the first encoder 109, and the read signal of the second head 110h, i.e., the second encoder 110 are sent substantially in real time to the stage control circuit 115.

The laser light source 102 irradiates the wafer 106 on the surface of the rotating and translating rotary stage 107 with laser light 103. The optical sensor 105 receives scattered light 104 of the laser light 103 from the surface of the wafer 106 and outputs a light intensity signal 101 corresponding to the light receiving intensity.

That is, the rotary stage 107 is rotated by the motor 111 while holding the wafer 106, and the base 112 performs translational motion, so that the wafer 106 moves relative to the point of irradiation of the laser light 103, resulting in the achievement of scanning of the laser light 103 over the entire wafer 106.

The intensity of the scattered light 104 received by the optical sensor 105 depends on a state on the surface of the wafer 106, e.g., the presence of foreign matter, the elevations on the surface, i.e., the unevenness, etc. Therefore, the surface of the wafer 106 is scanned with the laser light 103 thoroughly, and the coordinates of the irradiation point of the laser light 103 and the intensity of the scattered light 104 from its irradiation point are mapped in association with each other, so that it is possible to recognize the presence or absence of foreign matter and unevenness on the surface of the wafer 106, the positions of the foreign matter and unevenness, the size of the foreign matter and unevenness, and the like. The coordinates of the irradiation point of the laser light 103 are specified by the rotation angle from the angle reference of the rotary stage 107 and the position in the translational direction of the rotary stage 107.

Note that in the present application, the foreign matter existing on the surface of the wafer 106, concave and convex portions formed on the surface, and the like may be collectively referred to as “foreign matter”.

The stage control circuit 115 includes a first encoder rotation angle calculation circuit 116, a second encoder rotation angle calculation circuit 117, and a motor rotation control circuit 118.

The first encoder rotation angle calculation circuit 116 calculates the rotation angle of the rotary stage 107 based on the read signal of the graduations of the scale 108 from the first encoder 109, and outputs the calculated rotation angle as a first encoder rotation angle read value 120. The second encoder rotation angle calculation circuit 117 calculates the rotation angle of the rotary stage 107 based on the read signal of the graduations of the scale 108 from the second encoder 110, and outputs the calculated rotation angle as a second encoder rotation angle read value 122. The motor rotation control circuit 118 controls power supplied to the motor 111 based on an input control signal or a set sequence, and as a result, controls the rotational speed, i.e., angular speed of the rotary stage 107 or the rotational acceleration, i.e., angular acceleration of the rotary stage 107.

The computer 119 includes a selector 125 of a rotation angle read value and an image generation circuit 136. The selector 125 is connected to the first encoder rotation angle calculation circuit 116 and the second encoder rotation angle calculation circuit 117. The selector 125 receives a control signal or a signal indicating the rotational speed of the rotary stage 107 from the stage control circuit 115. The selector 125 selects, based on the received signal, either the first encoder rotation angle read value 120 or the second encoder rotation angle read value 122 as the rotation angle read value of the rotary stage 107 suitable for the rotation angle of the rotary stage 107 at this time. The selector 125 outputs the selected rotation angle read value to the image generation circuit 136 as an after-selection rotation angle read value 124.

The image generation circuit 136 acquires the after-selection rotation angle read value 124, a base translational direction position information 121, and the light intensity signal 101. The image generation circuit 136 specifies the coordinates of the irradiation point of the laser light 103 based on the after-selection rotation angle read value 124 and the base translational direction position information 121. Further, the image generation circuit 136 specifies the intensity of scattered light from the irradiation point of the laser light 103 based on the light intensity signal 101. The image generation circuit 136 maps, for each coordinate of the irradiation point of the laser light 103, the coordinate and the scattered light intensity from the irradiation point of the coordinate in association with each other, and generates an image representing an obtained map.

The stage control circuit 115 and the computer 119 are connected to the overall control circuit 139, and a user 140 can control these via the overall control circuit 139.

Further, the calculation control circuit 114 includes an unillustrated displayer, and can display a foreign matter position on the wafer 106 as an image on the screen of the displayer, or can display other various GUIs (Graphical User Interfaces). The user 140 can know the state of the surface of the wafer 106, i.e., the presence or absence of the foreign matter, the position of the foreign matter, the size of the foreign matter, and the like by viewing the image displayed on the displayer.

Note that all or part of the calculation control circuit 114 is constituted of, for example, a computer including a processor, and a semiconductor circuit device such as a semiconductor IC chip. Here, a description will be made about a hardware configuration of such a semiconductor circuit device.

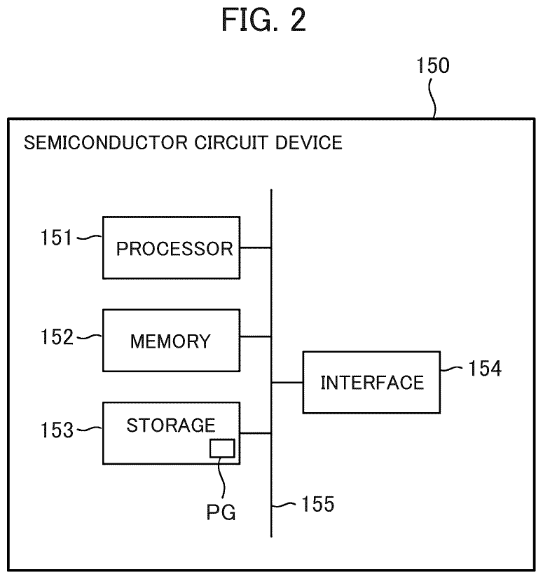

FIG. 2 is a diagram showing an example of a hardware configuration of the semiconductor circuit device according to the first embodiment. As shown in FIG. 2, the semiconductor circuit device 150 includes, for example, a processor 151, a memory 152, a storage 153, an interface 154, and a communication bus 155. The processor 151, the memory 152, the storage 153, and the interface 154 are each electrically connected to the communication bus 155 and configured to be able to communicate with each other via the communication bus 155.

In the semiconductor circuit device 150, a program PG for executing various processing is stored in the storage 153 or the memory 152. The processor 151 reads the program PG and develops and executes the program PG in the memory 152 to thereby realize various functional blocks, circuits, and the like. Note that the calculation control circuit 114 may be implemented by a single semiconductor circuit device or may be implemented by a plurality of semiconductor circuit devices. The calculation control circuit 114 may be implemented by a semiconductor device including a single processor or may be implemented by a semiconductor device including a plurality of processors.

Next, the rotary encoder mounted on the optical foreign matter inspection device 1 will be described in more detail.

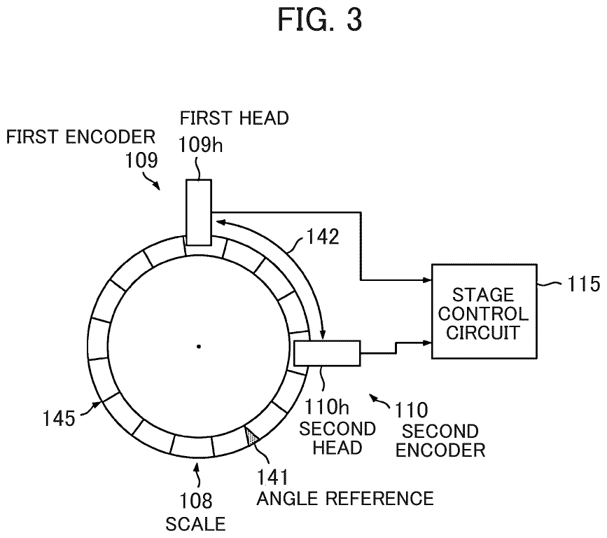

FIG. 3 is a diagram schematically showing a portion functioning as a rotary encoder of the optical foreign matter inspection device 1 according to the first embodiment. The portion functioning as the rotary encoder is a portion necessary for measuring the rotational angular position of the motor 111.

Generally, the rotary encoder is configured by a combination of a scale and a head. Each of the scale and the head is exclusively fixed to either a rotating body or a base supporting the rotating body. The head can specify the rotation angle of the scale, i.e., the rotation angle of the rotating body by reading the graduations of the scale.

The rotary encoder has a rotational speed range capable of coping with reading, which has been usually determined by specifications. The rotational speed range capable of coping with reading means a range of the rotational speed of the scale capable of reading the graduations of the scale with accuracy above a certain level. Here, it is assumed that the scale 108 is provided on the rotary stage 107 and is rotated integrally with the rotary stage 107. Therefore, it can also be said that the rotational speed range capable of supporting the reading of the rotary encoder is the rotational speed of the rotary stage 107 in which the reading accuracy of the graduations of the scale 108 is guaranteed at a certain level or more. Note that in the present application, the rotational speed range capable of supporting the reading of the head, i.e., the encoder, is also referred to as a supportable rotational speed range or a rotational speed range possible to correspond.

A plurality of rotary encoders are mounted on the optical foreign matter inspection device 1. The adaptable rotational speed range in the plurality of rotary encoders are different from each other, and the adaptable rotational speed ranges that are close to each other, overlap each other partially. Here, it is assumed that the optical foreign matter inspection device 1 is equipped with the two rotary encoders of the first encoder 109 and the second encoder 110.

In the present embodiment, as described above, the scale 108 is fixed to the rotary stage 107, and the first head 109h and the second head 110h are fixed to the base 112. The scale 108 is annular and is arranged on the back surface of the rotary stage 107. The rotation center of the rotary stage 107 and the geometrical center of the scale 108 are at the same position except for the mounting errors. Further, the first head 109h and the second head 110h are installed away from each other by an appropriate inter-head installation angle difference 142, e.g., 90°.

The first encoder 109 and the second encoder 110 share the scale 108, and the heads of both, i.e., the first head 109h and the second head 110h have adaptable rotational speed ranges different from each other, but some of the ranges overlap. Here, the adaptable rotational speed range of the first head 109h is relatively high, and the adaptable rotational speed range of the second head 110h is relatively low.

In the present embodiment, the scale 108 rotates as the rotary stage 107 rotates, and the scale 108 rotates relative to the first head 109h and the second head 110h, so that the rotation angle of the rotary stage 107 can be measured.

The rotary encoder according to the present embodiment assumes an incremental type as an example. The first head 109h and the second head 110h detect the graduations 145 engraved at an equal angle to the scale 108 and output a pulse signal at a read timing. The pulse signal is also referred to as an encoder pulse. The stage control circuit 115 measures the rotation angle of the rotary stage 107 by integrating the pulse signals output from the first head 109h and the second head 110h. Separately from the graduations 145, an angle reference 141 is engraved on the scale 108. The first head 109h and the second head 110h detects that the scale 108 turns once by detecting the angle reference 141. Further, the stage control circuit 115 measures the rotational speed of the rotary stage 107 based on a detection time difference of the angle reference 141.

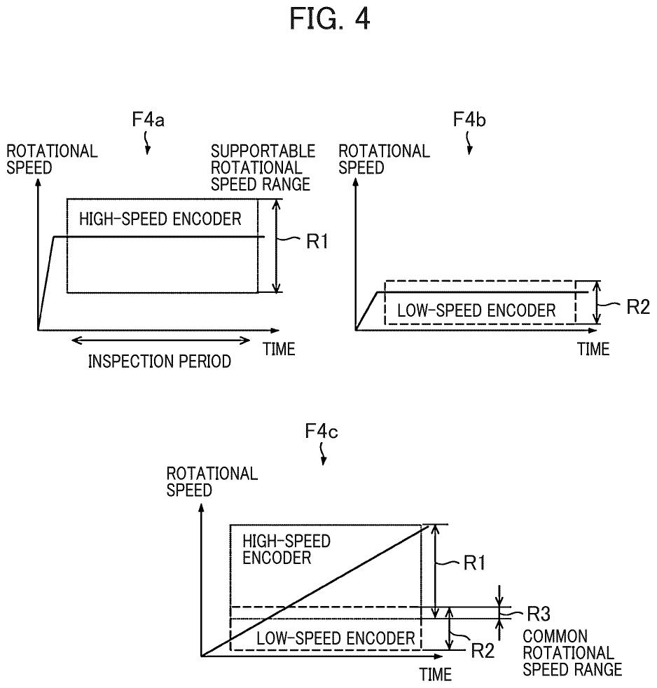

FIG. 4 is a diagram showing a temporal change in the rotational speed of the rotary stage during inspection in the first embodiment, and an adaptable rotational speed range of the head. The rotary encoder generally determines an adaptable rotational speed range on the specification due to a filter constant or the like inside the head. As shown in graphs F4a and F4b of FIG. 4, if the rotational speed during the inspection period is within the adaptable rotational speed range of the single rotary encoder, such as when the rotational speed of the rotary stage during the inspection period is constant, only the rotary encoder may be continued to be kept using during the inspection period.

For example, when the rotational speed of the rotary stage 107 is within an adaptable rotational speed range R1 of a high-speed encoder, or when the rotational speed of the rotary stage 107 is within an adaptable rotational speed range R2 of a low-speed encoder, it is not necessary to switch the used encoder.

However, as shown in a graph F4c of FIG. 4, when the rotational speed of the rotary stage during the inspection period changes and exceeds the adaptable rotational speed range of the single rotary encoder, a detection error of the read signal from the encoder increases at a rotational speed outside the adaptable rotational speed range, and the specific accuracy of the rotational angle position is reduced.

For example, when the rotational speed of the rotary stage 107 gradually increases, it is necessary to switch the encoder to be used from the low-speed one to the high-speed one when the rotation angle enters a common rotational speed range R3 which is an overlapping portion of the opposable rotational speed ranges R1 and R2.

In the present embodiment, as described above, the selector 125 selects either the first encoder rotation angle read value 120 and the second encoder rotation angle read value 122 as the rotation angle read value of the rotary stage 107 suitable for the current rotation angel of the rotary stage 107, based on the control signal received from the stage control circuit 115 or the signal indicating the rotational speed of the rotary stage 107. Therefore, in the present embodiment, the rotational speed of the rotary stage 107 that can be used can be increased without reducing the specific accuracy of the rotation angle position of the rotary stage 107.

### Flow of Processing in Optical Foreign Matter Inspection Device According to First Embodiment

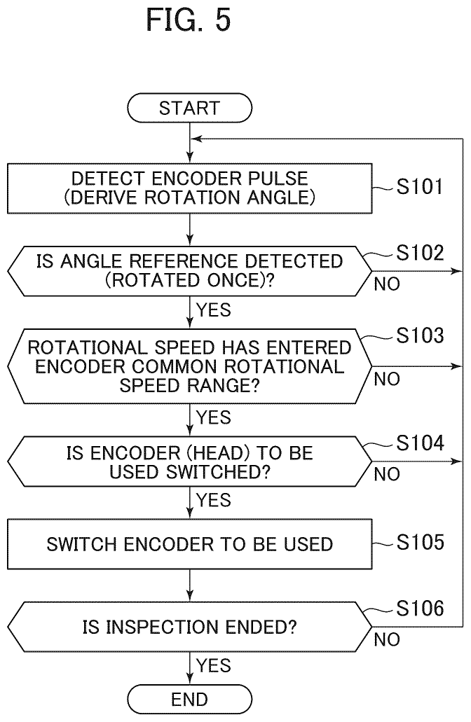

FIG. 5 is a flowchart showing an example of a flow of processing in the optical foreign matter inspection device according to the first embodiment. This flowchart shows a method of expanding the adaptable rotational speed range of the rotary stage 107 during the inspection of the optical foreign matter inspection device 1.

Thus, it is assumed that the flow of processing in the optical foreign matter inspection device according to the first embodiment will be described, but the processing related to the preparation until the start of the inspection has already been executed. Specifically, the motor rotation control circuit 118 drives and controls the motor 111 to rotate the rotary stage 107. Further, the overall control circuit 139 controls the laser light source 102 to irradiate the wafer 106 with the laser light 103. The optical sensor 105 receives the scattered light 104 from the wafer 106 and outputs the light intensity signal 101 corresponding to the light receiving intensity. The stage control circuit 115 is initially set as an encoder to be used by either the first encoder 109 or the second encoder 110 based on the rotational speed of the set rotary stage 107 or its temporal change.

As shown in FIG. 5, in Step S101, the processing of detecting an encoder pulse is performed. Specifically, the inspection is started by the control of each part by the overall control circuit 139. During the inspection, the stage control circuit 115 receives and detects a pulse signal which is a read signal from each of the first encoder 109 and the second encoder 110. The first encoder rotation angle calculation circuit 116 in the stage control circuit 115 calculates the rotation angle of the rotary stage 107, based on the pulse count number of the first encoder 109, and outputs the same to the selector 125. Further, the second encoder rotation angle calculation circuit 117 in the stage control circuit 115 calculates the rotation angle of the rotary stage 107, based on the pulse count number of the second encoder 110, and outputs the same to the selector 125.

The selector 125 selectively outputs either a rotation angle based on the pulse count number of the first encoder 109 or a rotation angle based on the pulse count number of the second encoder 110 to the image generation circuit 136 in response to control from the stage control circuit 115. The selector 125 outputs a rotation angle based on the pulse count number of the first encoder 109 when the encoder to be used is set to first encoder 109, and outputs a rotation angle based on the pulse counter number of the second encoder 110 when the encoder to be used is set to the second encoder 110. After the processing of Step S101 is completed, the processing step proceeds to Step S102.

In Step S102, the processing of determining whether or not the angle reference has been detected is performed. That is, the processing of determining whether or not the rotary stage 107 or the scale 108 has turned once is performed. Specifically, the stage control circuit 115 determines whether or not the angle reference 141 has been detected, based on a read signal from the encoder to be used or other encoder. Here, when it is determined that the angle reference 141 has been detected (S101: Yes), the processing step proceeds to Step S103. On the other hand, when it is determined that the angle reference 141 is not detected (S101: No), the processing step returns to Step S101.

In Step S103, the processing of determining whether or not the rotational speed has entered the common rotational speed range of the encoder is performed. Specifically, the stage control circuit 115 measures the rotational speed of the rotary stage 107 based on a signal from the first encoder 109 or the second encoder 110. Further, the stage control circuit 115 determines whether or not the measured rotational speed has entered the supportable common rotational speed range of each of the first encoder 109 and the second encoder 110. Here, when it is determined that the measured rotational speed has entered the common rotational speed range (S103: Yes) the processing step proceeds to Step S104. On the other hand, when is it determined that the measured rotational speed does not enter the common rotational speed range (S103: No), the processing step returns to Step S101.

In Step S104, the processing of determining whether to switch the encoder to be used is performed. That is, the processing of determining whether to switch the head to be used is performed. Specifically, the stage control circuit 115 determines whether to switch the encoder to be used, based on the set rotational speed for the rotary stage 107 or the temporal change in the set rotational speed.

For example, in the case in which the rotational speed of the rotary stage 107 is in a process of increasing with the lapse of time, that is, when the rotational speed is set to change from the supportable low-speed side rotational speed range of the second encoder 110 to the supportable high-speed side rotational speed range of the first encoder 109, determination is made to switch the encoder to be used from the second encoder 110 to the first encoder 109.

Further, for example, when the rotational speed of the rotary stage 107 is in a process of lowering with the lapse of time, that is, when the rotational speed is set to change from the supportable high-speed side rotational speed range of the first encoder 109 to the supportable low-speed side rotational speed range of the second encoder 110, determination is made to switch the encoder to be used from the first encoder 109 to the second encoder 110.

In addition, for example, when the rotational speed is set to be constant, it is determined that the encoder to be used is not switched.

When it is determined in the above determination that the encoder is switched (S104: Yes), the processing step proceeds to Step S105. On the other hand, when it is determined that the encoder is not switched (S104: No), the processing step returns to Step S101.

In Step S105, the processing of switching the encoder is performed. Specifically, the stage control circuit 115 controls the selector 125 in the computer 119 and executes processing of switching the encoder to be used or its signal. For example, when the encoder to be used is the first encoder 109, the encoder is switched to the second encoder 110. Further, when the encoder to be used is the second encoder 110, the encoder to be used is switched to the first encoder 109. When the switching of the encoder to be used is completed, the processing step proceeds to Step S106.

In Step S106, the processing of determining whether or not to end the inspection is performed. Specifically, it is determined whether or not to end the inspection, based on the set inspection sequence, the presence or absence of an error signal, and the like. When it is determined that the inspection is ended (S106: Yes), the processing step returns to Step S101 and the processing is continued. On the other hand, when it is determined that the inspection is not completed (S106: No.), the processing is ended.

As described above, according to the first embodiment, the detection of the encoder pulse is repeated until the rotary stage 107 rotates once, and the calculation of the rotation angle of the rotary stage 107 is continued. At the timing when the angle reference 141 of the scale 108 is detected, the rotational speed of the rotary stage 107 is specified. Based on the specified rotational speed, either the first head 109h or the second head 110h which can correspond to the rotational speed is defined as a head to be used to specify the rotation angle of the rotary stage 107. Also, when the specified rotational speed is within the common rotational speed range of the two rotary encoders, if necessary, the rotary encoder to be used is switched. Further, the rotation angle of the rotary stage 107 is determined based on the signal from the head to be used. Thus, by switching the signals of the rotary encoders within the common rotational speed range between the rotary encoders while monitoring the rotation speed of the rotary stage 107, the supportable rotational speed range of the rotary stage 107 during the inspection period can be expanded.

That is, according to the first embodiment, in the optical foreign matter inspection device, it is possible to realize high foreign matter position specification accuracy in a wider rotational speed range of the rotary stage.

### Second Embodiment

A second embodiment of the present invention relates to a function of reading a rotation angle position of a rotary stage in an optical foreign matter inspection device, and is configured to specify the rotation angle with higher accuracy while expanding a supportable rotational speed range. The optical foreign matter inspection device according to the second embodiment is based on, for example, the optical foreign matter inspection device according to the first embodiment, and further includes a function of correcting an error of a rotation angle based on a read pulse signal of a scale by an encoder. When the rotation angle based on a signal of a first encoder is used, the rotation angle is corrected using correction information for the first encoder. When the rotation angle based on a signal of a second encoder is used, the rotation angle is corrected using correction information for the second encoder.

Note that here, it is assumed that there is a deviation based on the molding accuracy or mounting accuracy of a scale between the rotation center of the scale and the geometrical center of the scale, and the above error occurs due to this deviation. Further, it is also assumed that the graduation of the scale is not arranged at equal intervals, there is a deviation between a rotational speed determined based on the time interval of the timing at which the graduation of the scale is detected by a first head or a second head and the actual rotational speed of the scale, and the above error occurs due to this deviation.

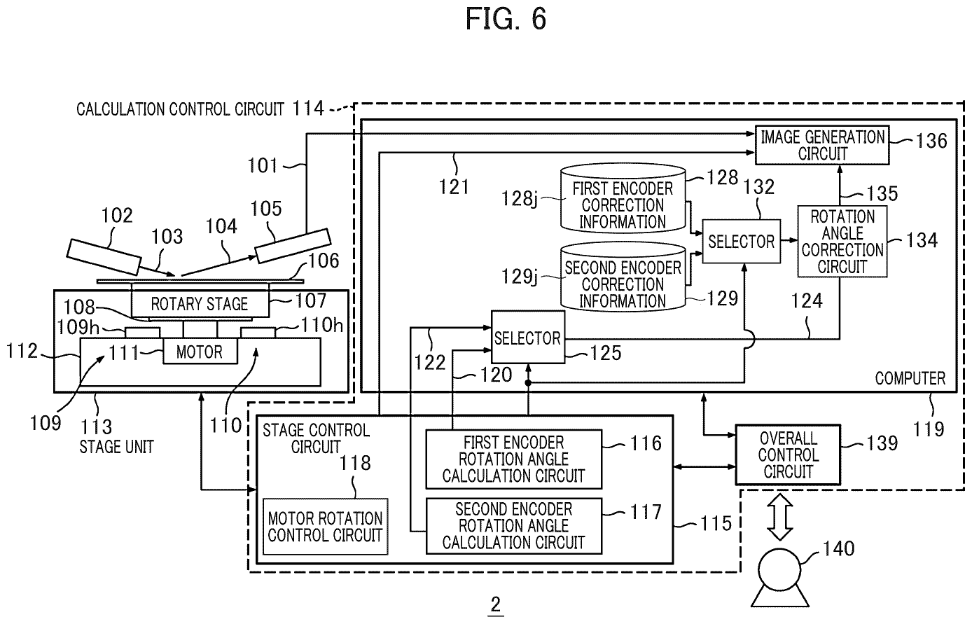

FIG. 6 is a diagram showing an example of a configuration of an optical foreign matter inspection device according to a second embodiment. As shown in FIG. 6, the optical foreign matter inspection device 2 according to the second embodiment has a configuration similar to that of the optical foreign matter inspection device 1 according to the first embodiment as a basic configuration. Then, a computer 119 in the optical foreign matter inspection device 2 further includes a first encoder correction information storage circuit 128, a second encoder correction information storage circuit 129, a selector 132 for encoder correction information, and a rotation angle correction circuit 134.

The first encoder correction information storage circuit 128 stores first encoder correction information 128j therein, and the second encoder correction information storage circuit 129 stores second encoder correction information 129j therein. The first encoder correction information 128j is correction information used for correction for bringing a rotation angle including an error output from the first encoder rotation angle calculation circuit 116 close to a true rotation angle. Also, the second encoder correction information 129j is correction information used for correction for bringing a rotation angle including an error output from the second encoder rotation angle calculation circuit 117 close to a true rotation angle.

The first encoder correction information 128j is information which may also be first head rotation angle correction information, and has a characteristic which changes when an installation rotation angle of a first head 109h and the amount of eccentricity of a scale 108 change. Similarly, the second encoder correction information 129j may also be second head rotation angle correction information, and is information having a characteristic which changes when an installation rotation angle of a second head 110h and the amount of eccentricity of the scale 108 change.

Based on a control signal from a stage control circuit 115, the selector 132 switches the correction information used to correct the rotation angle to either the first encoder correction information 128j or the second encoder correction information 129j. When the rotation angled to be used is the rotation angle output from the first encoder rotation angle calculation circuit 116, the selector 132 outputs the first encoder correction information 128j to the rotation angle correction circuit 134. Further, when the rotation angle to be used is the rotation angle output from the second encoder rotation angle calculation circuit 117, the selector 132 outputs the second encoder correction information 129j to the rotation angle correction circuit 134.

The rotation angle correction circuit 134 inputs the rotation angle output from a selector 125 and the correction information output from the selector 132, corrects the input rotation angle using the input correction information, and outputs a corrected rotation angle 135 to an image generation circuit 136.

The image generation circuit 136 specifies the position of an irradiation point of laser light 103, based on base translational direction position information 121 input from the stage control circuit 115 and the corrected rotation angle 135 of the rotary stage 107 input from the rotation angle correction circuit 134. Further, the image generation circuit 136 specifies the scattered light intensity of the laser light 103 from the position of the irradiation point based on a light intensity signal 101 input from the optical sensor 105. Then, the image generation circuit 136 maps the position of the irradiation point of the specified laser light 103 and the scattered light intensity of the laser light 103 from the position of the irradiation point in association with each other to generate an image.

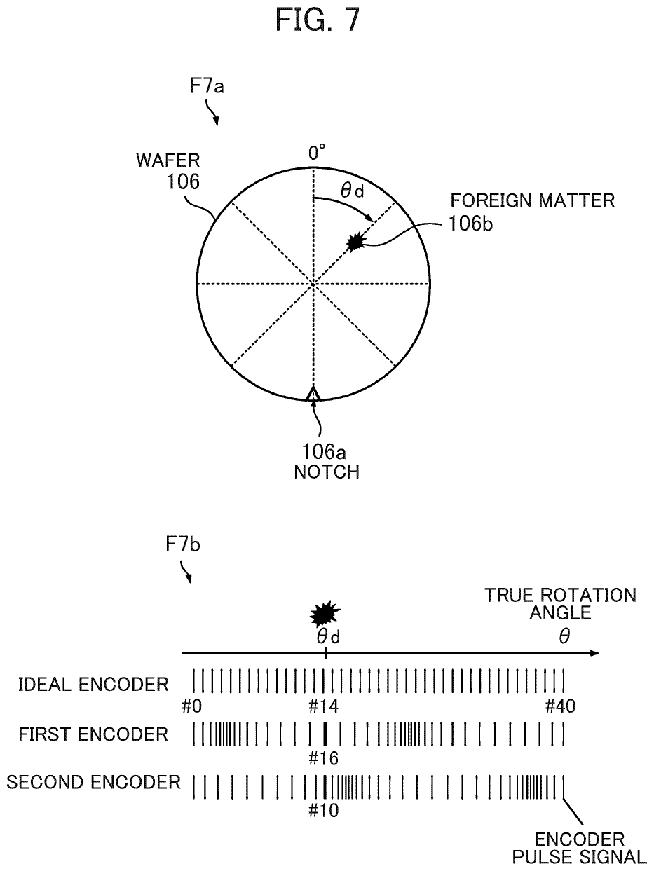

FIG. 7 is a diagram for describing that a detection rotation angle of foreign matter on a wafer differs between an ideal rotary encoder and an actual rotary encoder in the second embodiment. As shown in FIG. 7, the wafer 106 has a notch 106a which serves as a reference for the rotation angle position. As an example, as shown in F1a in an upper stage of FIG. 7, it is assumed that the upper direction of the drawing when the notch 106a is arranged in the lower direction of the drawing is set to a rotation angle 0°, and foreign matter 106b exists in the position of a rotation angle θd in a clockwise direction. F7b in a lower stage of FIG. 7 shows the timing at which the horizontal axis is a true rotation angle θ and the pulse of the rotary encoder is detected.

In an ideal encoder, a pulse signal of the encoder is detected at equal intervals with respect to a linear change in the true rotation angle θ. Here, the pulse signal of the ideal encoder corresponding to the rotation angle θd of the foreign matter 106b is assumed to be the 14th pulse signal from the state of the rotation angle θ=0. On the other hand, in the first encoder 109 and the second encoder 110 which are the actual rotary encoders, the detection interval of the pulse signal relative to the rotation angle θ is not constant due to the eccentricity of the scale, the distortion of the scale 108, and the like. Therefore, the pulse signal of the encoder corresponding to the rotation angle θd at which the foreign matter 106b is detected may deviate from the pulse count number of the ideal encoder, i.e., the pulse number as in the case of the 16th in the first encoder 109 and the 10th in the second encoder 110.

It is assumed that the rotary encoder is capable of detection not by an actual rotation angle but only by the graduations of the scale 108, and conversion from the pulse count number counted in accordance with the graduations of the scale 108 to the rotation angle θ is an ideal encoder. Therefore, if the deviation is not corrected, the detection rotation angle of the foreign matter 106b is different between the case in which the first encoder 109 is used, and the case in which the second encoder 110 is used. Further, it is possible that they may also differ from the actual rotation angle θd of the foreign matter 106b.

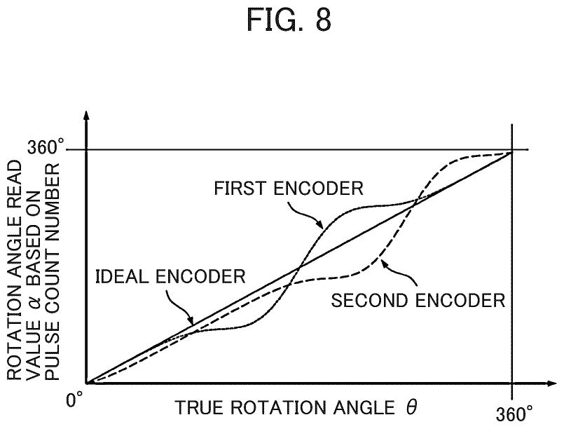

FIG. 8 is a diagram showing an example of a change in a rotation angle α based on the pulse count number of the encoder with respect to the true rotation angle θ in the second embodiment. In a graph shown in FIG. 8, the horizontal axis is a true rotation angle θ, and the vertical axis is a rotation angle α based on the pulse count number of the encoder. The rotation angle α based on the pulse count number is obtained by integrating the number of pulse signals output from the encoder in response to the detection of the graduations of the scale, and multiplying its integrated value by an angle corresponding to the interval of the graduations.

In FIG. 8, the rotation angle read value α based on the pulse counter number of the ideal encoder is represented by a straight line drawn by a solid line. The rotation angle read value α based on the pulse count number of the first encoder 109 is represented by a curve drawn by a broken line having a short interval. Further, the rotation angle read value α based on the pulse count number of the second encoder 110 is represented by a curve drawn by a broken line having a long interval. Incidentally, although the rotation angle read value α by the encoder is originally discrete, but here, the resolution of the encoder, that is, the total number of pulses detected in one rotation is continuously shown assuming that the total number of pulses is sufficiently large.

As shown in FIG. 8, in the ideal encoder, the relationship of the rotation angle read value α by the encoder with respect to the true rotation angle θ is represented by a straight line. However, in the actual encoder, since the pulse interval is coarse, the relationship of the rotation angle read value α by the encoder with respect to the true rotation angle θ is represented by a curve which starts at 0° and ends at 360°, and takes a shape of a curve different depending upon the installation position of the head. If the difference between the straight line corresponding to the ideal encoder and the curve corresponding to the actual encoder in this graph is known in advance, the true rotation angle θ can be obtained by adding the difference to the rotation angle read value α by the actual encoder. That is, in the computer 119, the difference is stored as correction information, and a true rotation angle θ can be calculated by correcting the rotation angle read value α of the encoder by use of the correction information.

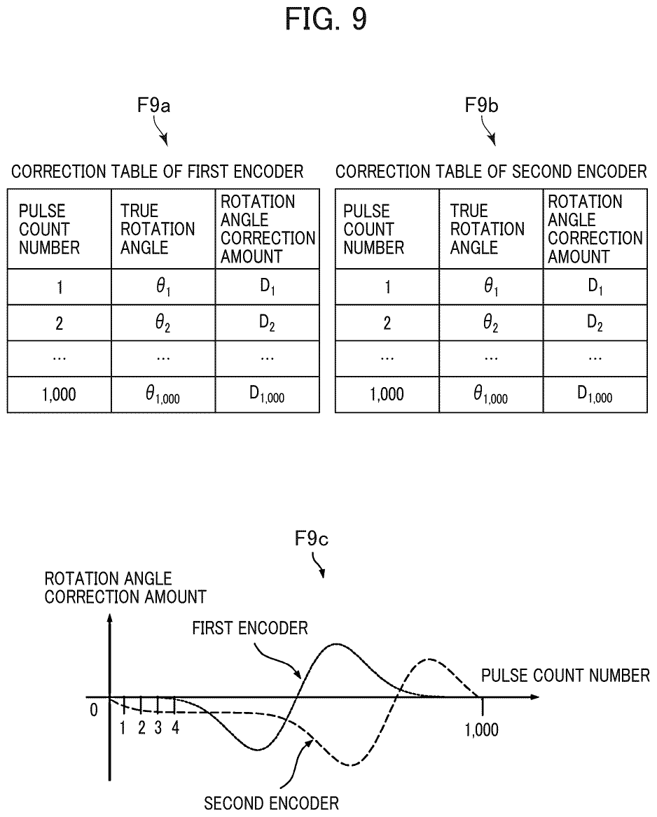

FIG. 9 is a diagram showing the concept of the correction information of the encoder according to the second embodiment and an example thereof. Here, it is assumed that the read pulse count number of the encoder corresponding to a rotation angle of 360° is 1000. That is, the resolution of the rotation angle is assumed to be 360°/1000. F9a on the upper-stage left side of FIG. 9 shows a correction table which is an example of the correction information of the first encoder 109, and F9b on the upper-stage right side of FIG. 9 shows a correction table which is an example of the correction information of the second encoder 110. In these correction tables, the pulse count number of the encoder and the amount of correction of the rotation angle for obtaining the true rotation angle are associated with each other.

F9c in a lower stage of FIG. 9 is an example of a graph obtained by plotting the rotation angle correction amount for the pulse count number for each pulse count number with the horizontal axis as the pulse count number of the encoder and the vertical axis as the rotation angle correction amount. In this graph, there is shown in a broken line of a short interval, an example of a graph curve corresponding to the first encoder 109. There is shown in a broken line of a long interval, an example of a graph curve corresponding to the second encoder 110.

From the above, for example, for all the encoders mounted on the optical foreign matter inspection device 2, an engineer checks in advance the pulse count number of the encoder, the true rotation angle corresponding to the pulse count number, the rotation angle correction amount, and the like for each pulse count number of the encoder. Further, for each encoder and each pulse count number, a correction table in which the pulse count number and the true rotation angle or the rotation angle correction amount are associated with each other is held in the computer 119 as correction information. Here, the computer 119 stores such a correction table therein as the first encoder correction information 128j and the second encoder correction information 129j.

Then, the computer 119 refers to the correction table for encoder each time at the timing when the pulse of the encoder used is detected, and corrects the rotation angle read value based on the pulse count number of the encoder using the corresponding rotation angle correction amount. Alternatively, the true rotation angle corresponding to the pulse count number of the encoder is directly specified by referring to the correction table for the encoder each time at the timing when the pulse of the encoder used is detected. This is substantially the same processing as obtaining the true rotation angle by correcting the rotation angle read value. The computer 119 can easily determine the true rotation angle by executing such processing.

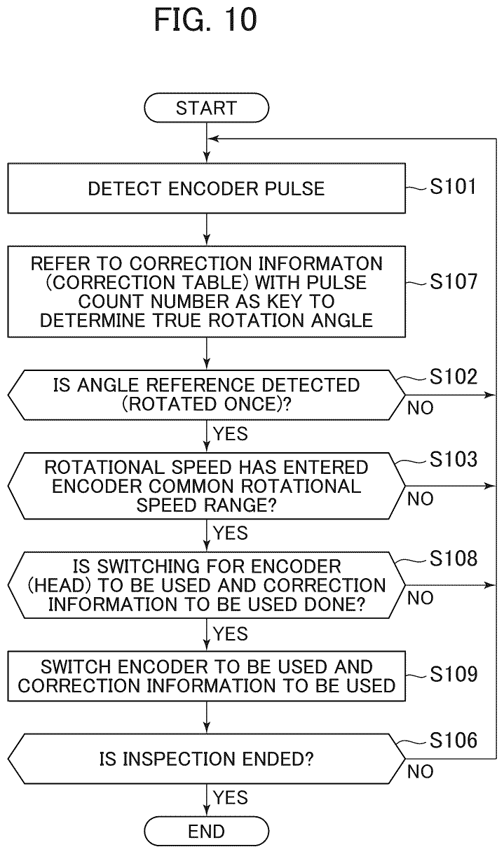

FIG. 10 is a flowchart showing an example of a flow of processing in the optical foreign matter inspection device 2 according to the second embodiment. According to this flowchart, there are shown a method determining a true rotation angle based on the pulse count number of the rotary encoder and a method of expanding a supportable rotation speed range.

The processing contents of Steps S101, S102, S103, and S106 in the flowchart shown in FIG. 10 are substantially the same as the processing contents of Steps of the same code in the flowchart shown in FIG. 5. Therefore, the detailed description of the processing of these Steps will be omitted.

First, in Step S101, the processing of detecting the encoder pulse is performed. Through this processing, the rotation angle of the rotary stage 107 is derived based on the pulse count number from the encoder to be used.

Next, in Step S107, the processing of determining the true rotation angle is performed by referring to the correction information using the pulse count number as a key. Specifically, the selector 132 receives control from the stage control circuit 115 and outputs the correction information corresponding to the used encoder to the rotation angle correction circuit 134. For example, when the used encoder is the first encoder 109, the first encoder correction information 128j is output to the rotation angle correction circuit 134. The rotation angle correction circuit 134 inputs the rotation angle based on the pulse count number of the used encoder from the selector 125, and inputs the correction information corresponding to the used encoder from the selector 132.

The rotation angle correction circuit 134 corrects the input rotation angle read value using the rotation angle correction amount obtained by referring to the input correction information, and outputs the corrected rotation angle 135 indicating the true rotation angle to the image generation circuit 136.

Incidentally, in the present example, the first encoder rotation angle calculation circuit 116 or the second encoder rotation angle calculation circuit 117 in the stage control circuit 115 calculates the rotation angle based on the pulse count number of the encoder, and transmits the calculated rotation angle to the rotation angle correction circuit 134 via the selector 125.

On the other hand, as another example, the first encoder rotation angle calculation circuit 116 or the second encoder rotation angle calculation circuit 117 may transmit the pulse count number itself of the encoder to the rotation angle correction circuit 134 via the selector 125. In this case, the rotation angle correction circuit 134 refers to the correction information based on the input pulse count number, directly reads the corresponding true rotation angle, and outputs the corrected rotation angle 135 indicating the true rotation angle to the image generation circuit 136.

A method of obtaining the true rotation angle may be either of the above two methods, and this also applies to other embodiments.

Next, in Step S102, processing is performed to determine whether or not the angle reference has been detected, that is, whether or not the rotary stage 107 or the scale 108 has been rotated once. Here, when it is determined that the angle reference 141 has been detected (S101: Yes), the processing step proceeds to Step S103. On the other hand, when it is determined that the angle reference 141 is not detected (S101: No), the processing step returns to Step S101.

In Step S103, the processing of determining whether or not the rotational speed has entered the common rotational speed range of the encoder is performed. Here, when it is determined that the measured rotational speed has entered the common rotational speed (S103: Yes), the processing step proceeds to Step S108. On the other hand, when it is determined that the measured rotational speed has not entered the common rotational speed (S103: No), the processing step returns to Step S101.

In Step S108, processing is performed to determine whether to switch between the encoder to be used, i.e., the head to be used and the correction table to be used. Specifically, the stage control circuit 115 determines whether to switch between the head to be used and the correction information to be used, based on the set rotational speed or the temporary change in the set rotational speed.

For example, when the rotational speed is set to change from the supportable low-speed side rotational speed range of the first encoder 109 to the supportable high-speed side rotational speed range of the second encoder 110, determination is made to switch the encoder to be used from the first encoder 109 to the second encoder 110. Also, for example, when the set rotational speed is a constant speed, determination is made not to switch the encoder to be used. When it is determined that the encoder to be used is switched (S108: Yes), the processing step proceeds to Step S109. On the other hand, when it is determined that the encoder to be used is not switched (S108: No), the processing step returns to Step S101.

In Step S109, the processing of switching the used encoder and the correction information to be used is performed. Specifically, the stage control circuit 115 controls the selector 125 and the selector 132 in the computer 119, switches the signal of the encoder to be used, and executes the processing of switching the correction information to be used to the correction information corresponding to the switched encoder. For example, when the signal from the encoder to be used is a signal from the first encoder 109, the signal from the encoder to be used is switched to a signal from the second encoder 110, and the correction information to be used is switched from the first encoder correction information 128j to the second encoder correction information 129j. Further, when the signal from the encoder to be used is of the signal from the second encoder 110, the signal from the encoder to be used is switched to the signal from the first encoder 109. When the switching of the signal of the encoder to be used and the correction information to be used is completed, the processing step proceeds to Step S106.

In Step S106, the processing of determining whether or not to end the inspection is performed. Specifically, it is determined whether or not to end the inspection, based on the set inspection sequence, the presence or absence of an error signal, and the like. When it is determined that the inspection is ended (S106: Yes), the processing step returns to Step S101 and the processing is continued. On the other hand, when it is determined that the inspection is not completed (S106: No), the processing is ended.

From the above, according to the second embodiment, it is possible to correct the error of the rotation angle by the encoder by referring to the correction table being the correction information, using the pulse count number at the timing when the encoder pulse is detected, i.e., the pulse number as a key, and by reading the necessary information.

For example, in the case in which there is a deviation between the rotation center of the scale 108 and the geometrical center of the scale 108, and the rotation center of the scale 108 is defined as the rotation center of the rotation angle, the installation rotation angle of the first head 109h and the installation rotation angle of the second head 110h are assumed to be different from each other. In this case, it is possible to correct the error of the rotation angle read value caused by this.

Further, it is assumed that for example, the graduations of the scale 108 are not arranged at equal intervals, there is a deviation between the rotational speed determined based on the time interval of the timing at which the graduations of the scale 108 are detected by the first head 109h or the second head 110h, and the actual rotational speed of the scale 108, and when the rotation center of the scale 108 is defined as the rotation center of the rotation angle, the installation rotation angle of the first head 109h and the installation rotation angle of the second head 110h are different from each other. In this case, it is possible to correct the error of the rotation angle read value caused by this.

In addition, the correction table to be used is also switched simultaneously with the signal from the encoder to be used at the timing when the angle reference is detected, so that the supportable rotational speed range of the foreign matter inspection device can be expanded while reducing the deviation of the foreign matter detection position accompanying the switching of the encoder to be used. That is, according to the second embodiment, it is possible to realize the foreign matter inspection device having high foreign matter position specification accuracy in the wider rotational speed range of the rotation table.

### Third Embodiment

A third embodiment of the present invention relates to a function of reading a rotation angle position of a rotary stage in an optical foreign matter inspection device, and is configured to generate correction information used to specify a rotation angle with high accuracy while expanding a supportable rotational speed range. The optical foreign matter inspection device according to the third embodiment includes, for example, a function of generating correction information by using the optical foreign matter inspection device according to the second embodiment as a basis and further rotating a rotary stage under a setting condition and recording a relative time at which a pulse signal of an encoder at that time is detected.

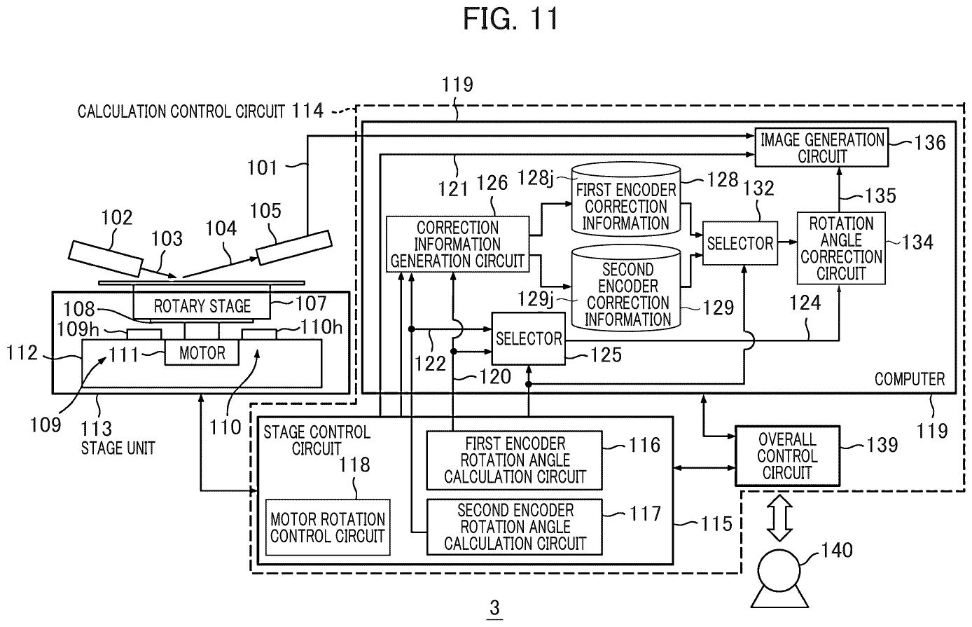

FIG. 11 is a diagram showing an example of a configuration of the optical foreign matter inspection device according to the third embodiment. As shown in FIG. 11, the optical foreign matter inspection device 3 according to the third embodiment has a configuration similar to that of the optical foreign matter inspection device 2 according to the second embodiment as a basic configuration. Then, a computer 119 in the optical foreign matter inspection device 3 further includes a correction information generation circuit 126.

The correction information generation circuit 126 acquires information relating to a relationship between a rotation angle of a rotary stage 107 and a detection timing of a pulse signal of an encoder from a stage control circuit 115, and generates encoder correction information described in the second embodiment, based on the acquired information. Hereinafter, a first generation method of the encoder correction information will be described.

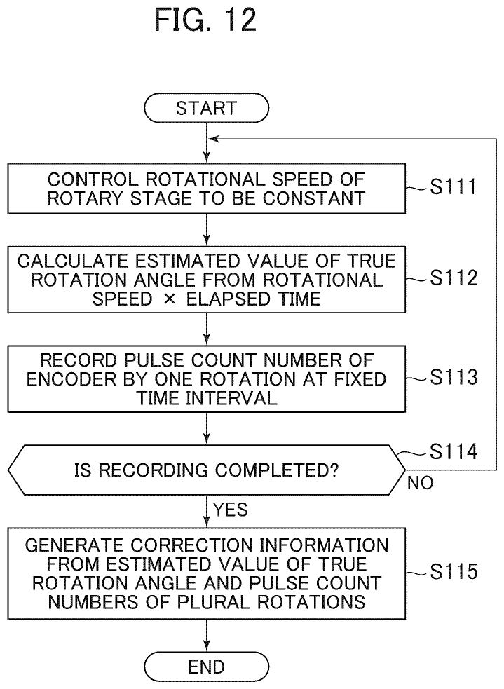

FIG. 12 is a flowchart showing an example of a flow of processing by the first generation method of encoder correction information in the optical foreign matter inspection device according to the third embodiment. Note that a method of generating encoder correction information related to a single encoder will be described here. Therefore, when generating both first encoder correction information 128j related to a first encoder 109 and second encoder correction information 129j related to a second encoder 110, it is necessary to execute processing twice when the target encoder is set to the first encoder 109 and when the target encoder is set to the second encoder 110.

As shown in FIG. 12, first, in Step S111, the processing of controlling the rotational speed of the rotary stage to be constant is performed. Specifically, a motor rotation control circuit 118 in the stage control circuit 115 controls driving of a motor 111 so that the rotary stage 107 rotates at a constant rotational speed set according to a control signal related to the generation of correction information from an overall control circuit 139. However, strictly, the actual rotational speed of the rotary stage 107 varies within the range of accuracy of rotational speed control of the motor 111 about the set rotational speed. When the rotation of the rotary stage 107 is stabilized to some extent, the processing step proceeds to Step S112.

In Step S112, the processing of calculating an estimated value of a true rotation angle from the multiplication of a rotational speed and an elapsed time is performed. Specifically, at plural time points corresponding to one rotation or more of the rotary stage 107, the correction information generation circuit 126 sets the product of a set value of the rotational speed of the rotary stage 107 and an elapsed time as an estimated value of an actual rotation angle, and calculates an estimated value of a true rotation angle corresponding to one rotation of the rotary stage 107. Thereafter, the processing step proceeds to Step S113.

In Step S113, the processing of recording the pulse count number of the encoder over one rotation of the rotary stage at a fixed time interval is performed. Specifically, on the basis of the information obtained from the stage control circuit 115, the correction information generation circuit 126 records the pulse count number of the encoder at plural times at a constant time interval, i.e., at plural time points, corresponding to one or more rotations of the rotary stage 107. The constant time interval is defined to be, for example, a time which is sufficiently shorter than the time obtained by dividing the time required for one rotation of the rotary stage 107 by the number of graduations of 360° of a scale 108. When the recording of the pulse count number is completed, the processing step proceeds to Step S114.

In Step S114, the processing of determining whether to end recording is performed. Specifically, the correction information generation circuit 126 determines whether or not to end the processing of recording the pulse count number of the encoder. For example, when the recording of the preset number of rotations is completed, it is determined that the recording is ended. On the other hand, when the recording of the preset number of rotations is not completed, it is determined that the recording is not ended. The preset number of rotations is, for example, 10 rotations to 100 rotations or the like. When it is determined that the recording is ended (S114: Yes), the processing step proceeds to Step S115. On the other hand, when it is determined that the recording is not ended (S114: No), the processing step returns to Step S111.

In Step S115, the processing of generating correction information of the encoder is performed through the estimated value of the true rotation angle and the pulse count number of plural rotations. Specifically, the correction information generation circuit 126 compares, at the same time for each time, the estimated value of the true rotation angle with the rotation angle obtained when the encoder is assumed to be ideal based on the pulse count number of the encoder, and obtains the difference therebetween.

The correction information generation circuit 126 further performs statistical processing such as averaging on the difference obtained for each time for the plural rotations of the rotary stage 107, reduces a variation in the difference resulting from the variation in the rotational speed, and calculates a correction amount of the rotation angle with respect to the pulse count number of the encoder. Alternatively, the correction information generation circuit 126 specifies a true rotation angle with respect to the pulse count number of the encoder. With such processing, the correction information generation circuit 126 generates a correspondence relationship between the pulse count number of the encoder and the correction amount of the rotation angle or the true rotation angle as encoder correction information. When the generation of the correction information is completed, the processing of generating the correction information is ended.

As described above, in the present embodiment, the motor 111 is controlled so that the rotational speed of the rotary stage 107 becomes constant. As a result, the true rotational speed of the rotary stage 107 varies within the accuracy range of the rotational speed control of the motor 111 with the set rotational speed as the center. Here, the product of the set value of the rotational speed and the elapsed time is taken as the estimated value of the rotation angle, and the estimated value is recorded for one rotation of the rotary stage 107 together with the rotation angle based on the pulse count number of the encoder. Such recording is repeated over a plurality of rotations of the rotary stage 107, and statistical processing such as averaging the difference between the estimated value of the true rotation angle and the rotation angle based on the pulse count number of the encoder for a plurality of rotations is performed. Consequently, the variation in the rotational speed of the rotary stage 107 is reduced, and correction information high in accuracy is generated.

As the cause of the variation in the rotational speed, there are considered a random one caused by an accidental external force and a periodic object caused by the vibration of the rotating body. However, these are different from the error of the rotation angle depending on the encoder itself, and are not always caused to have errors of the same size at the same rotation angle. For example, a temporally random one is easily imagined to attenuate its size by stacking statistics. Further, since the vibration of the rotating body depends on the rotational speed of the rotating body, even at the same rotation angle, the error of the rotation angle detected by the rotation angle is different depending on the set value of the rotational speed. Therefore, the acquisition of the correction information using the method according to the present embodiment is justified by continuing the measurement of the multiple number of rotations while changing the set value of the rotational speed.

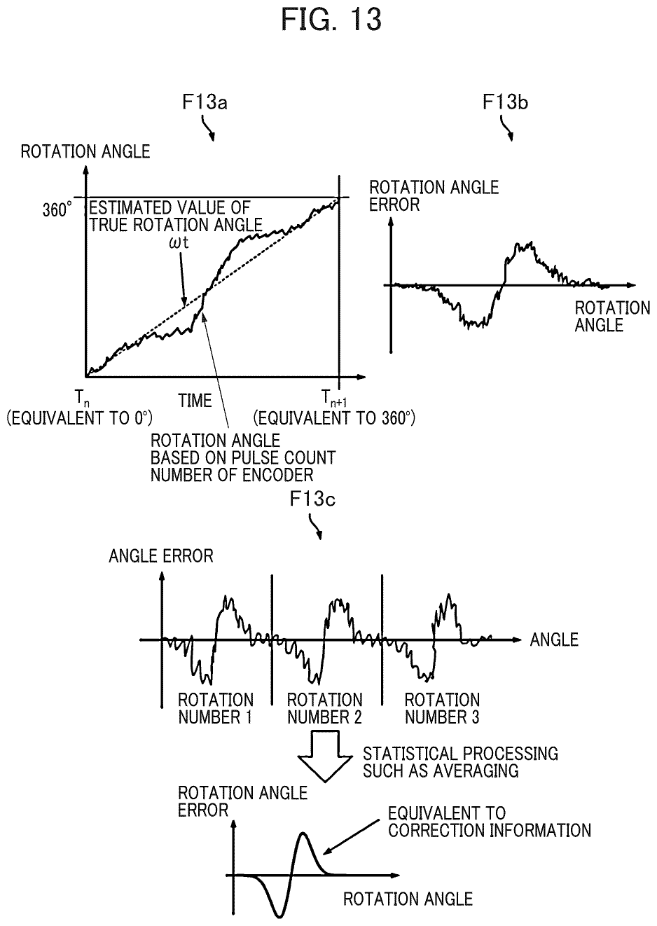

FIG. 13 is a diagram for describing the first generation method of the correction information according to the third embodiment in detail. F13a on the upper-stage left side of FIG. 13 shows a plot of the estimated value of the true rotation angle over one rotation of the rotary stage 107 and the rotation angle based on the pulse count number of the encoder against time. In is the time at which the angle reference is detected for the nth time. The straight line is obtained by multiplying the set value of the rotational speed, i.e., the set angular speed ω with the elapsed time, which is the estimated value of the true rotation angle. On the other hand, the rotation angle based on the pulse count number of the encoder becomes a curve including the variation in the rotational speed in addition to the error possessed by the encoder itself. F13b on the upper-stage right side of FIG. 13 shows the result of calculating the difference between the estimated value of the true rotation angle and the rotational speed based on the pulse count number of the encoder, and converting the horizontal axis to the rotation angle. When the unit of the horizontal axis is converted from the time to the angle, a formula for calculating the estimated value of the true rotation angle shown in F13a is used.

Although F13b is a calculation result for one rotation of the rotary stage 107, as shown in F13c, this is calculated over plural rotations, and statistical processing such as averaging is performed, so that the variation in the rotational speed can be reduced, and only an error of the encoder itself can be extracted. The error possessed by the encoder itself is, that is, correction information of the encoder. As an example, if the variation in the speed is the normal distribution, the variation in the rotational speed can be reduced to 1/VN by averaging the calculation result for N rotations.

As described above, according to the third embodiment, there is provided the first generation method of generating the first encoder correction information 128j and the second encoder correction information 129j. The first generation method is a method of generating the correction information of the encoder by comparing the rotation angle read value based on the pulse count number of the encoder and the estimated value of the true rotation angle derived by the theoretical calculation while being controlled so that the rotational speed of the rotary stage 107 becomes constant. Further, in the optical foreign matter inspection device 3, the correction information generation circuit 126 performs processing according to the first generation method, and can automatically generate the first encoder correction information 128j and the second encoder correction information 129j.

Incidentally, in the third embodiment, the calculation control circuit 114 stores a table in which the pulse count number of the encoder and the rotation angle correction amount are associated as correction information, specifies the rotation angle read value based on the pulse count number obtained from the encoder to be used, i.e., the head, corrects the rotation angle read value by the rotation angle correction amount while referring to the table, and derives the true rotation angle.

However, the calculation control circuit 114 may directly derive the true rotation angle by storing the table in which the pulse count number of the encoder and the true rotation angle are directly associated with each other, as correction information, and referring to the table based on the obtained pulse count number. In this case, since the processing of determining the rotation angle read value from the pulse count number or correcting the rotation angle read value using the rotation angle correction amount is essentially omitted, the true rotation angle can be identified at high speed. Note that this method can be similarly applied to other embodiments.

### Fourth Embodiment

Similarly to the third embodiment, a fourth embodiment of the present invention relates to a function of reading a rotation angle position of a rotary stage in an optical foreign matter inspection device, and is configured to generate correction information used to specify the rotation angle with high accuracy while expanding a supportable rotational speed range. However, a method of generating the correction information is different from the method described in the third embodiment.

That is, the optical foreign matter inspection device according to the fourth embodiment has the same configuration as the optical foreign matter inspection device according to the third embodiment as shown in FIG. 11, but a correction information generation method in a correction information generation circuit 126 is different from the third embodiment.

Hereinafter, a description will be made about a second generation method of the correction information in the correction information generation circuit 126 according to the fourth embodiment.

In the third embodiment, the rotational speed of the rotary stage 107 is controlled to be constant by the motor 111, but when the control accuracy of the motor 111 is too low with respect to the resolution of the encoder to be targeted, the variation in the rotational speed becomes relatively large, and even with statistical processing, it is not possible to completely reduce the variation with the realistic number of samples, and it may not be possible to calculate the correction information. In the present embodiment, this problem is solved.

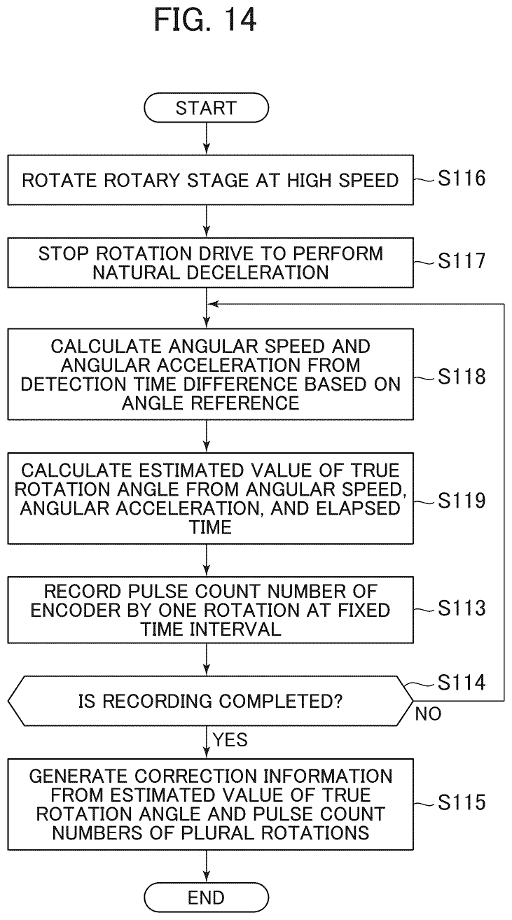

FIG. 14 is a flowchart showing an example of a flow of processing by the second generation method of the encoder correction information in the optical foreign matter inspection device according to the fourth embodiment. Note that even here, similarly to the third embodiment, a method of generating encoder correction information related to a single encoder will be described. Therefore, when generating both first encoder correction information 128j related to a first encoder 109 and second encoder correction information 129j related to a second encoder 110, it is necessary to execute processing twice when the target encoder is set to the first encoder 109 and when the target encoder is set to the second encoder 110.

The processing contents of Step S113, S114, and S115 in the flowchart shown in FIG. 14 are substantially the same as the processing contents of Steps of the same code in the flowchart shown in FIG. 12. Therefore, the detailed description of the processing of these Steps will be omitted.

As shown in FIG. 14, first, in Step S116, the processing of rotating a rotary stage 107 at a high speed is performed. Specifically, a motor rotation control circuit 118 in a stage control circuit 115 controls the driving of the motor 111 so as to accelerate the rotation until the rotary stage 107 reaches the set rotational speed in accordance with a control signal related to the generation of correction information from an overall control circuit 139. When the rotational speed reaches the set value, the processing step proceeds to Step S117.

In Step S117, the processing of stopping the rotation drive to perform natural deceleration is carried out. Specifically, the motor rotation control circuit 118 stops the supply of power to the motor 111 and naturally decelerates the rotational speed of the rotary stage 107 according to a constant friction coefficient. The processing step proceeds to Step S118.

In Step S118, the processing of calculating the angular speed and the angular acceleration from the detection time difference based on the angle reference is performed. Specifically, the correction information generation circuit 126 calculates the angular speed in the rotation of the rotary stage 107 at plural times and the angular acceleration of the deceleration, from the detection time difference when an angle reference 141 is repeatedly detected within a period in which the rotational speed of the rotary stage 107 is naturally decelerated. Thereafter, the processing step proceeds to Step S119.

In Step S119, the processing of calculating a predicted value of a true rotation angle from the angular speed, the angular acceleration, and the elapsed time is performed. Specifically, the correction information generation circuit 126 calculates a predicted value of the true rotation angle at each time, based on the calculated angular speed, angular acceleration, and elapsed time at multiple times. Thereafter, the processing step proceeds to Step S113.

In Step S113, the processing of recording the pulse count number of the encoder over one rotation of the rotary stage at a fixed time interval is performed. The processing step proceeds to Step S114.

In Step S114, the processing of determining whether to end recording is performed. When it is determined that the recording is ended (S114: Yes), the processing step proceeds to Step S115. On the other hand, when it is determined that the recording is not completed (S114: No), the processing step returns to S118.

In Step S115, the processing of generating correction information of the encoder is performed through the estimated value of the true rotation angle and the pulse count number of plural rotations. When the generation of the correction information is completed, the processing of generating the correction information is ended.

As described above, in the present embodiment, the motor 111 is controlled such that the rotational speed of the rotary stage 107 is once accelerated to a high speed and then naturally decelerated. Then, the angular speed and the angular acceleration of the deceleration are calculated from the detection time difference of the angle reference 141 within a period in which the rotational speed is naturally decelerated. Then, the estimated value of the true rotation angle is calculated from the angular speed, the angular acceleration, and the elapsed time. Thereafter, similarly to the third embodiment, the rotation angle based on the pulse count number of the encoder is acquired, the difference between the estimated value of the true rotation angle and the rotation angle based on the pulse count number is taken, and the difference at each time in the multiple rotations is statistically processed to generate the correction information of the encoder. In the present embodiment, since the acquisition of data required for the generation of the correction information all ends within a period in which the rotary stage 107 is naturally decelerated, the motor 111 does not control the rotational speed of the rotary stage 107. Therefore, in the second generation method of the correction information, the control accuracy of the motor 111 is not a problem.

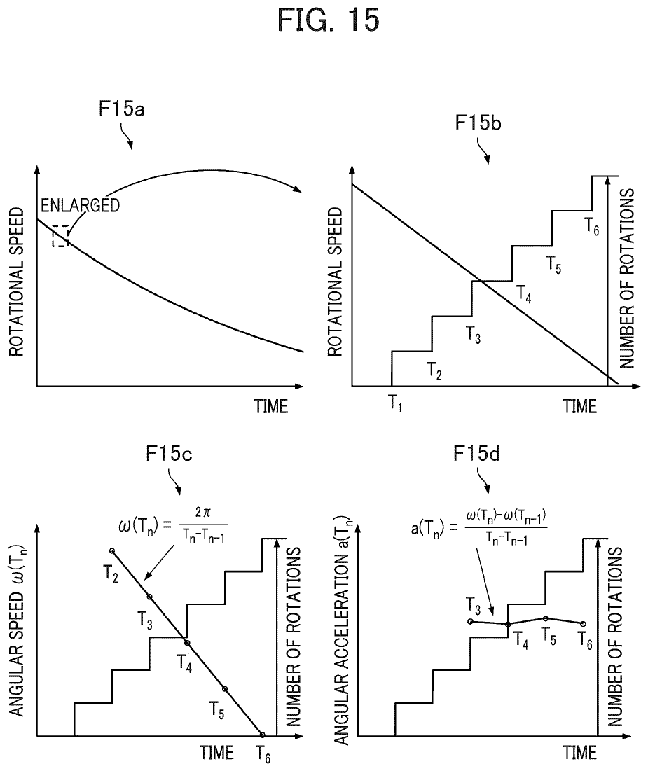

FIG. 15 is a diagram for describing a calculation method of the angular speed and the angular acceleration in the fourth embodiment. F15a on the upper-stage left side of FIG. 15 represents a temporal change in the rotational speed of the rotary stage 107. Here, it is assumed that after accelerating the rotary stage 107 by the motor 111 to a high speed, the speed control is stopped, and the rotary stage naturally decelerates exponentially with being applied with the resistance proportional to the speed such as the air resistance. In general, if the rotary stage 107 on which the wafer 106 is placed is heavy, and the rotary stage 107 is rotated at a high speed, it is possible to consider that since the rotational energy is high, the influence exerted on the angular acceleration change is light even if there is disturbance, and if the rotary stage 107 is within a short period, the equiangular acceleration motion is performed.

F15b on the upper-stage right side of FIG. 15 represents in an enlarged form, a portion of a period of any continuous six rotation of the graph of the temporal change of the rotational speed, and the number of times that the angle reference 141 is detected is also described as the number of rotations. In is the time at which the angle reference is detected for the nth time. In the enlarged region, it can be seen that the temporal change of the angular speed is almost straight, and the angular speed is decelerated at equiangular acceleration.

Since the angle reference 141 is detected once every time the rotary stage 107 rotates 360°, the estimated value ω (Tn) of the angular speed at the nth detection time Tn of the angle reference can be calculated from the detection time difference of the angle reference 141 as shown in F15c on the lower-stage left side of FIG. 15. Similarly to this, as shown in F15d on the lower-stage right side of FIG. 15, the estimated value a (Tn) of the angular acceleration at the detection time Tn can be calculated. From the above, since the estimated values of the angular speed and the angular acceleration at the nth detection time Tn of the angle reference can be calculated, the temporal change θ(t) in the true rotation angle in the next rotation cycle can be predicted by the following formula (1).

$$[ Formula 1 ]$$

$$θ ( r ) = ω ( {T}_{n} ) t + \frac{1}{2} a ( {T}_{n} ) {t}^{2} \qquad ( 1 )$$

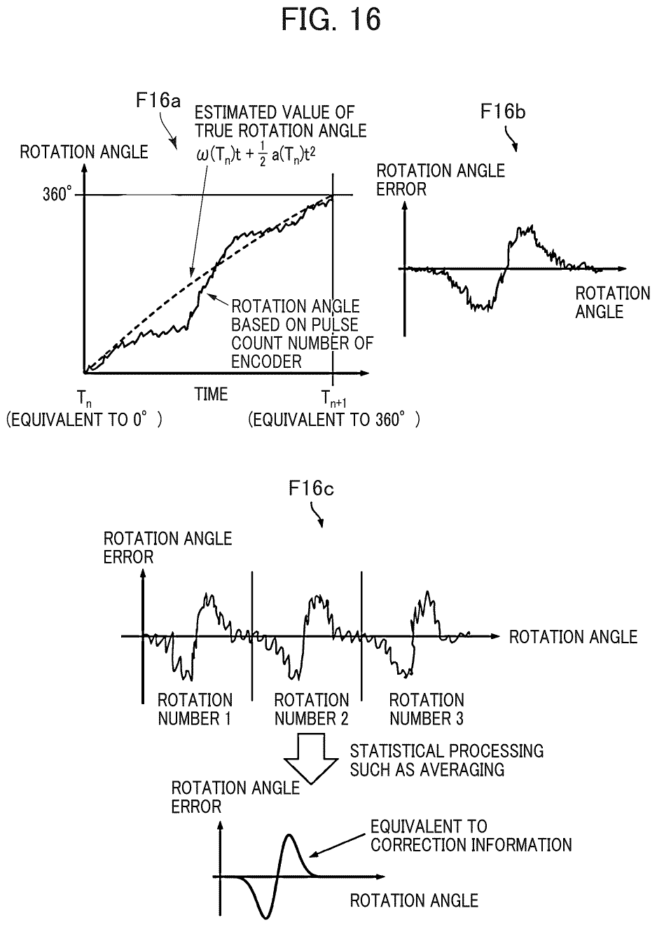

FIG. 16 is a diagram for describing a flow of calculation of the correction information according to the fourth embodiment. F16a on the upper-stage left side of FIG. 16 is a plot of an estimated value of a true rotation angle calculated in the above formula (1) and a rotation angle based on the pulse count number of the encoder during a period between the nth detection time Tn of the angle reference and the next detection time Tn+1. The estimated value of the rotation angle is different from the third embodiment and becomes a secondary curve. The rotation angle based on the pulse count number of the encoder includes the variation in the rotational speed at the time of natural deceleration in addition to the error possessed by the encoder itself. Then, F16b on the upper-stage right side of FIG. 16 is one obtained by calculating the difference between the two, and converting the horizontal axis to the angle and plotting the same. When the unit of the horizontal axis is converted from the time to the angle, the above formula (1) is used. Thereafter, as shown in F16c of the lower stage in FIG. 16, similarly to the third embodiment, this is repeated for a plurality of rotations, and then statistical processing such as averaging is performed, thereby making it possible to generate correction information in which the variation in speed has been cancelled.

Thus, according to the fourth embodiment, there is provided the second generation method of generating the first encoder correction information 128j and the second encoder correction information 129j. The second generation method is a method of comparing the rotation angle read value based on the pulse count number of the encoder with the estimated value of the true rotation angle derived by the theoretical calculation while the rotational speed of the rotary stage 107 is naturally decelerated by a constant resistance or a friction coefficient to thereby generate correction information of the encoder. Further, in the optical foreign matter inspection device 3, the correction information generation circuit 126 performs processing according to the first generation method, and can automatically generate the first encoder correction information 128j and the second encoder correction information 129j.

### Fifth Embodiment

Similarly to the third embodiment, a fifth embodiment of the present invention relates to a function of reading a rotation angle position of a rotary stage in an optical foreign matter inspection device, and is configured to generate correction information used to specify a rotation angle with high accuracy while expanding a supportable rotational speed range. However, in the fifth embodiment, a method of generating the correction information is different from the methods described in the third embodiment and the fourth embodiment.

That is, the optical foreign matter inspection device according to the fifth embodiment has the same configuration as the optical foreign matter inspection device according to the third embodiment as shown in FIG. 11, but a method of generating correction information in a correction information generation circuit is different from the third embodiment and the fourth embodiment.

Hereinafter, a description will be made about a third generation method of the correction information in the correction information generation circuit 126 according to the fifth embodiment. In the third embodiment and the fourth embodiment, in order to generate correction information for a target encoder, it was necessary to actually use a pulse signal from the target encoder. Therefore, when n encoders are mounted on the optical foreign matter inspection device, it is necessary to execute the processing of generating the correction information over n times. On the other hand, in the fifth embodiment, an example 5 will explain a method of generating correction information of another encoder from correction information of any encoder.

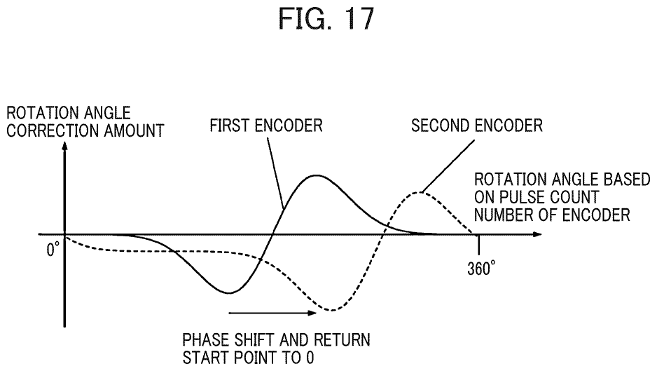

FIG. 17 is a diagram showing an example of a graph obtained by plotting a rotation angle correction amount for a rotation angle based on the pulse count number of the encoder according to the fifth embodiment. Here, as in the optical foreign matter inspection device according to each embodiment described above, it is assumed that a first encoder 109 and a second encoder 110 are mounted, and these encoders are comprised of a plurality of heads each having the same installation radius, i.e., a first head 109h and a second head 110h, and single scale 108 shared by these heads. Further, it is assumed that the rotation angle correction amount of the second encoder 110 configured by the second head 110h in advance is already determined. In this case, the rotation angle correction amount of the first encoder 109 constituted of the first head 109h can be obtained by phase-shifting, that is, cyclically shifting the rotation angle correction amount of the second encoder 110 by the difference in the installation angle between the first head 109h and the second head 110h, and adjusting an offset so that the start point becomes 0. This is because the rotation angle correction amount can utilize the property that it is a periodic function of the cycle 360°.

The fifth embodiment can also be combined with the third embodiment or the fourth embodiment. For example, it is assumed that a single scale and two or more heads different in a corresponding rotational speed range are mounted in the optical foreign matter inspection device. First, the correction information generation circuit 126 obtains the correction information by applying the method of generating the correction information according to the third or fourth embodiment to an encoder A comprised of a head a relatively highest in the supportable rotational speed range. Next, the correction information generation circuit 126 can generate correction information of an encoder B comprised of a head b by phase-shifting the correction information of the encoder A by an installation angle difference between the head a and the other head b. Even when the head, i.e., the encoder is three or more, it is possible to determine the known correction information by using a similar concept, that is, by phase-shifting by the installation angle difference of the head.

From the above, according to the fifth embodiment, there is provided the third generation method of generating second encoder correction information 129j from first encoder correction information 128j or generating the first encoder correction information 128j from the second encoder correction information 129j. The third generation method is a method of generating rotation angle correction information for the other head by phase-shifting rotation angle correction information for one head of the first head 109h and the second head 110h by an installation angle difference between the first head 109h and the second head 110h using the property that the rotation angle correction amount is a periodic function of the cycle 360°. Further, in the optical foreign matter inspection device 3, the correction information generation circuit 126 performs processing according to the third generation method, and can automatically generate the first encoder correction information 128j or the second encoder correction information 129j.

In addition, according to the fifth embodiment, when a plurality of encoders are configured by sharing a single scale with a plurality of heads, the rotation angle correction amounts of all other encoders configured by other heads can be obtained only by determining the rotation angle correction amount of the encoder comprised of one head thereof. Therefore, when the plurality of encoders are configured by sharing the single scale with the plurality of heads, the rotation angle correction amounts of all the encoders, i.e., the correction information can be obtained efficiently in a short period of time.

### Sixth Embodiment

In the optical foreign matter inspection device, the correction information is generated and stored regardless of the size of the error of the encoder to be mounted, and the rotation angle of the rotary stage 107 obtained by the encoder can be corrected. However, when the error of the encoder itself is very large, it is necessary to adjust or replace the encoder itself before correction. In the sixth embodiment, in view of this situation, a description will be made about a method of enabling state diagnosis of the encoder by periodically obtaining and grasping the rotation angle correction amount of the encoder even after the optical foreign matter inspection device has been delivered to the customer destination.

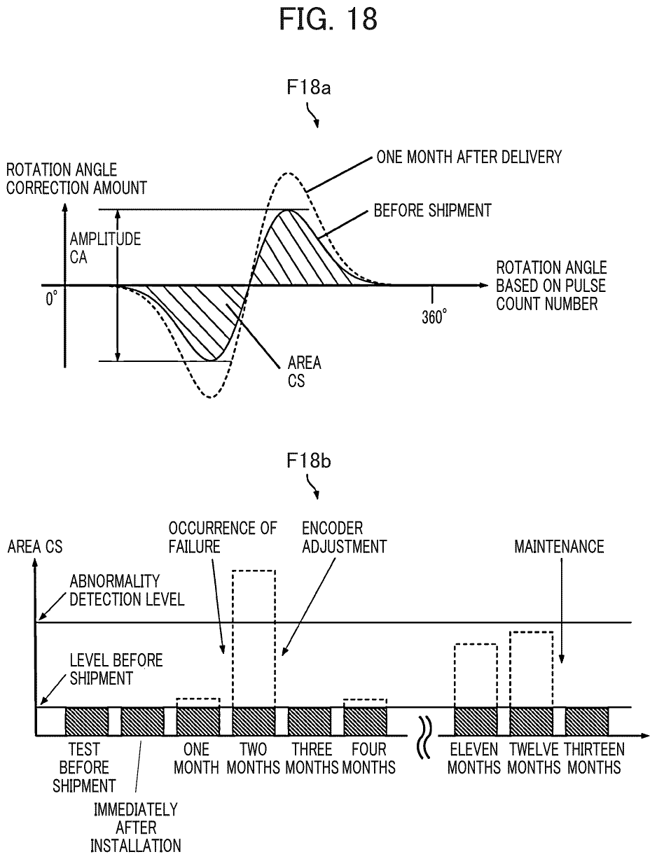

FIG. 18 is a diagram for describing a method of diagnosing a state of the encoder according to the sixth embodiment. F18a in the upper stage of FIG. 18 is an example in which the rotation angle correction amount of the encoder mounted on the optical foreign matter inspection device is plotted with respect to the rotation angle based on the pulse count number of the encoder. In F18a, a solid line indicates a graph curve of a rotation angle correction amount measured before the device shipment, and a broken line indicates a graph curve of a rotation angle correction amount obtained after the first month after the delivery to the customer destination. It can be seen that the rotation angle correction amount is larger in area CS or amplitude CA than before the device shipment. Actually, while continuing the use of the optical foreign matter inspection device, the scale may shift from its installation position due to the centrifugal force or the like, the eccentricity amount may become larger than before shipment, and the error amount of the encoder to be corrected may be large.

Here, for example, the area CS of the graph of the rotation angle correction amount or the amplitude CA, etc. are calculated to make it possible to index the correction intensity of the rotation angle correction amount of the encoder, that is, the error level of the rotation angle of the encoder. Then, before shipment of the device or after delivery to the customer destination, the correction information of the encoder is periodically measured, and each time, this index value, i.e., the area CS or the amplitude CA is calculated and stored, whereby the temporal change in the state of the encoder can be monitored.

F18b in the lower stage of FIG. 18 shows an example of a monitor result of the area CS of the graph of the rotation angle correction information in a period from when the optical foreign matter inspection device is delivered to the customer destination until the lapse of 13 months. First, the rotation angle correction amount of the encoder is measured and stored before the device is shipped. Then, after the device is delivered and installed to the customer destination, the rotation angle correction amount is measured every month, and the encoder is corrected using the rotation angle correction amount until the next measurement. Before shipment and immediately after installation, it can be seen that the area CS is minimum, i.e., the error of the encoder is the smallest, but the area is increased with the lapse of time.

Assume that between the first month and the second month, such a failure that the installation position of the encoder deviates due to, for example, an earthquake or the like occurs. Then, in the graph of the rotation angle correction amount measured immediately after this, it can be seen that the area CS is extremely increased and has exceeded an abnormality detection level set in advance. When the abnormality is detected in this way, the error can be reduced to the same level before shipment by adjusting the encoder. After that, when there is no large increase in error, but the error is increasing slowly, the error can be reduced to the same level before shipment as expected by performing adjustment to the encoder again in 12th month periodic maintenance.

The optical foreign matter inspection device according to the sixth embodiment has a function capable of setting a correction information generation mode. The correction information generation mode is a mode in which the processing of generating the rotation angle correction amount of the encoder as correction information is automatically or semi-automatically performed. Further, the device also has a function to urge the user to periodically set the correction information generation mode, for example, at a month interval, or to forcibly set the correction information generation mode. In addition, the device also has a function of notifying whether the error level of the encoder or its error level exceeds an abnormal level.

These functions are realized by, for example, configuring the overall control circuit 139 so that the overall control circuit 139 executes preset processing and automatically controls each circuit or the like. In order to configure the overall control circuit 139 in this way, for example, the program PG stored in the storage 153 and executed by the processor 151 may be designed such that the overall control circuit 139 executes the set processing described above.

As described above, according to the sixth embodiment, there is provided the method of diagnosing the state of the encoder mounted on the optical foreign matter inspection device. The method of diagnosing the state of the encoder is a method of periodically determining a rotation angle correction amount of the encoder even after the optical foreign matter inspection device has been delivered to the customer destination, confirming a temporal change in the correction amount, and performing state diagnosis such as whether the encoder is in an abnormal state or is likely to become abnormal in the future. In the optical foreign matter inspection device 3, the correction information generation circuit 126 in the calculation control circuit 114 periodically determines the rotation angle correction amount of the encoder in accordance with the state diagnosis method, and the calculation control circuit 114 outputs the temporal change in the correction amount to the user, so that the user can diagnose the state of the encoder in the optical foreign matter inspection device.

### Seventh Embodiment

A seventh embodiment is a management system for managing a plurality of optical foreign matter inspection devices by a management device. The management device monitors the states of the plurality of optical foreign matter inspection devices and measures a machine difference between the devices. That is, the optical foreign matter inspection device according to the seventh embodiment is configured to be connectable to the management device via a server.

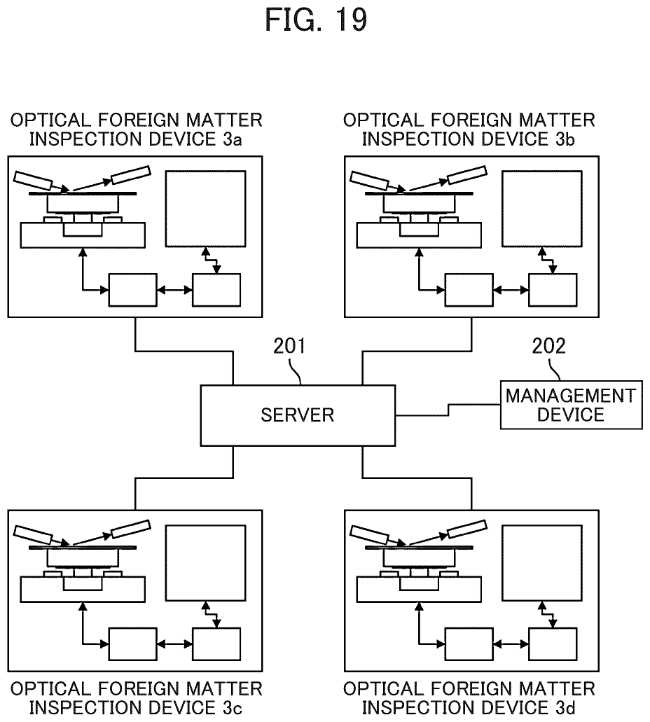

FIG. 19 is a diagram showing an example of a configuration of the management system according to the seventh embodiment. The optical foreign matter inspection devices 3a to 3d shown in FIG. 19 have substantially the same configuration as the optical foreign matter inspection device according to the third embodiment. The optical foreign matter inspection devices 3a to 3d are connected to the management device 202 via the server 201, and each of the optical foreign matter inspection devices 3a to 3d and the management device 202 can communicate with each other. Note that in the present example, although the number of devices connected to the server 201 is four, the number of devices is not particularly limited.

Similarly to the sixth embodiment, each of the optical foreign matter inspection devices 3a to 3d periodically measures correction information, and then indexes the correction information and transmits its index value to the management device 202. The management device 202 monitors the index values periodically transmitted from these four optical foreign matter inspection devices 3a to 3d. Thus, the management device 202 can grasp whether or not the error of the encoder tends to be large in any device, and can predict which device is likely to require encoder adjustment next. Further, these monitor results can also be displayed in a GUI (Graphical User Interface), and its result can be easily understood by an administrator. Note that here, the administrator simply means a user who handles the management device 202.

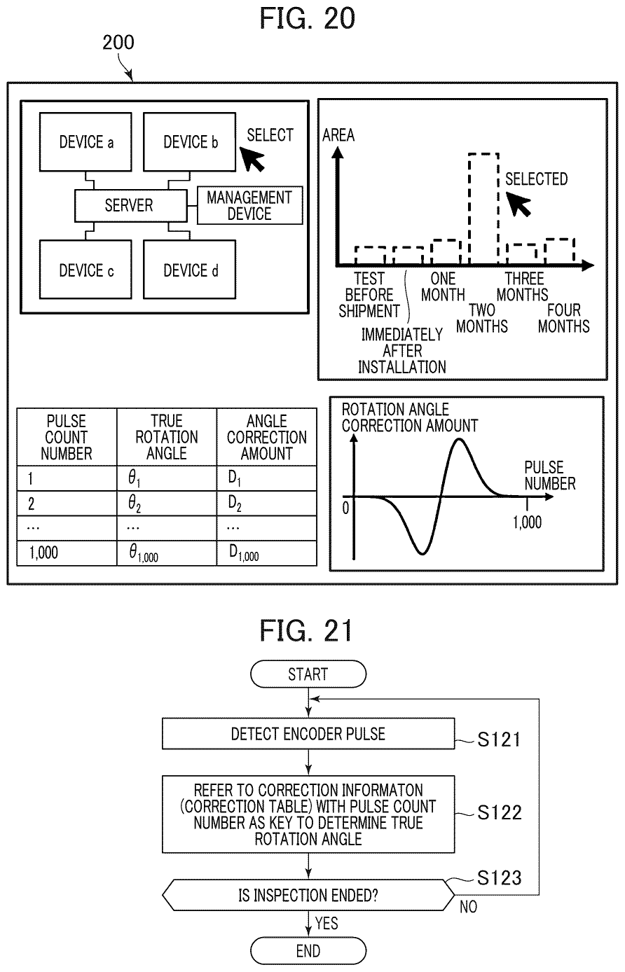

FIG. 20 is an example of an image of a GUI displaying monitor results of the plurality of optical foreign matter inspection devices according to the seventh embodiment. For example, the management device 202 displays the image 200 of the GUI as shown in FIG. 20. In the image 200 of the GUI, the arrangement of a plurality of devices connected to the management device 202 is displayed on the upper left. When the administrator selects one of these plural devices on the image 200 of the GUI, a periodic monitor result of correction information of an encoder of the selected device is displayed as shown on the upper right of the image 200. Further, when the administrator selects any data of the monitor results on the image 200 of the GUI, the actual measurement result of the correction information, such as the rotation angle correction amount of the encoder is displayed as shown in the lower left and lower right of the image 200. The management device 202 may output a plurality of rotation angle correction information received from the plurality of connected optical foreign matter inspection devices in a comparable manner.

As described above, according to the seventh embodiment, the monitor results of the plurality of connected optical foreign matter inspection devices are displayed on the image of the GUI of the management device 202, whereby the administrator can intuitively grasp the temporary change in the state of the encoder between the plural devices, predict the deterioration of the machine difference, identify, at high speed, the cause when the machine difference deteriorates, and reduce the early machine difference due to the encoder adjustment and replacement.

### Eighth Embodiment

An optical foreign matter inspection device according to an eighth embodiment includes a single encoder, and uses only the single encoder to correct a rotation angle based on the pulse count number of the encoder.

In the case where the angular position can be specified even by a single rotary encoder, such as when the rotational speed of the rotary stage 107 during inspection is constant, there is no need to switch the encoder during the inspection. However, even in that case, since there is an error in the rotation angle read value based on the pulse count number of the encoder, there is a need to correct the rotation angle based on the pulse count number of the encoder in order to specify the accurate rotation angle position. Therefore, in the eighth embodiment, a description will be made about a method of correcting the rotation angle of the encoder when only a single encoder is used without switching the encoder.

FIG. 21 is a flowchart showing an example of a flow of processing in the optical foreign matter inspection device according to the eighth embodiment.

In the eighth embodiment, as in the second embodiment, the correction information, i.e., the correction table of the encoder to be corrected is stored in advance.

As shown in FIG. 21, first, in Step S121, the processing of detecting an encoder pulse is performed.

Next, in Step S122, at the timing when the encoder pulse is detected, the pulse count number, i.e., the pulse number is used as a key to refer to the correction table and read the true rotation angle.

Next, in Step S123, the processing of determining whether or not to end the inspection is performed. When it is determined that the inspection is ended (S123: Yes), the inspection ends. On the other hand, when it is determined that the inspection is not ended (S123: No), the processing step returns to Step S121. That is, in the present embodiment, since the encoder is not switched, the inspection ends as it is when the determination that the inspection is ended is met.

As described above, according to the eighth embodiment, there is provided the method of correcting the rotation angle read value based on the pulse signal of the encoder using the stored rotation angle correction information when only the single encoder is used without switching the encoder used. In the optical foreign matter inspection device, the calculation control circuit 114 stores the rotation angle correction information for the head, i.e., encoder correction information. The rotation angle correction information for the head has the characteristic of changing when the installed rotation angle of the head changes. The calculation control circuit 114 specifies the rotation angle read value of the rotary stage 107 based on the signal from the head, and corrects the specified rotation angle read value using the rotation angle correction information for the head. Thus, even when only the single encoder is used, the true rotation angle can be obtained by correcting the rotation angle read value using the correction information.

It should be noted that the present invention is not limited to the embodiments described above, and includes various modifications. For example, the embodiments described above have been described in detail to simply describe the present invention, and are not necessarily required to include all the described configurations. It is also possible to replace part of the configuration of one embodiment with the configuration of another embodiment, and it is also possible to add the configuration of another embodiment to the configuration of one embodiment. In addition, each of the above-described configurations, functions, processing units, processing means, etc. may be realized in hardware by such as designing some or all of them with integrated circuits, for example. Further, each of the above-described configurations, functions, etc. may be realized in software by a processor interpreting and executing a program which realizes each function. Information such as programs, tables, files, etc. which realize each function may be located on a memory, a recording device such as a hard disk or SSD (Solid State Drive), or a recording medium such as an IC card, an SD card, a DVD, etc.

### LIST OF REFERENCE SIGNS

1, 2, 3 . . . optical foreign matter inspection device, 101 . . . light intensity signal, 102 . . . laser light source, 103 . . . laser light, 104 . . . scattered light, 105 . . . optical sensor, 106 . . . wafer, 107 . . . rotary stage, 108 . . . scale, 109 . . . first encoder, 109h . . . first head, 110 . . . second encoder, 110h . . . second head, 111 . . . motor, 112 . . . base, 113 . . . stage unit, 114 . . . calculation control circuit, 115 . . . stage control circuit, 116 . . . first encoder rotation angle calculation circuit, 117 . . . second encoder rotation angle calculation circuit, 118 . . . motor rotation control circuit, 119 . . . computer, 120 . . . first encoder rotation angle read value, 121 . . . base translational direction position information, 122 . . . second encoder rotation angle read value, 124 . . . after-selection rotation angle read value, 125 . . . selector, 126 . . . correction information generation circuit, 128 . . . first encoder correction information storage circuit, 128j . . . first encoder correction information, 129 . . . second encoder correction information storage circuit, 129j . . . second encoder correction information, 132 . . . selector, 134 . . . rotation angle correction circuit, 135 . . . corrected rotation angle, 136 . . . image generation circuit, 139 . . . overall control circuit, 140 . . . user, 141 . . . angle reference, 142 . . . inter-head installation angle difference, 145 . . . graduation, 201 . . . server, 202 . . . management device.

1. An optical foreign matter inspection device which detects foreign matter on a surface of a sample, comprising:
a rotary stage on which the sample is placed;
a motor which rotates the rotary stage;
a base to which the motor is fixed;
an annular scale provided on the rotary stage;
a first head and a second head which are installed on the base and which detect graduations of the scale and output a signal;
a laser light source which irradiates laser light toward the surface of the sample;
an optical sensor which receives scattered or reflected light of the laser light from the surface of the sample and outputs a signal according to the intensity of the received light; and
a calculation control circuit which performs processing of controlling the motor and processing of specifying a position of the foreign matter on the sample based on a signal from the first head or the second head and a signal from the optical sensor, wherein
a rotational speed range of the rotary stage capable of being supported by the first head and a rotational speed range of the rotary stage capable of being supported by the second head are relatively different from each other so as to overlap partially, and
the calculation control circuit
determines, based on the rotational speed of the rotary stage, either of the first head and the second head as a head to be used for specifying a rotation angle of the rotary stage, and
determines a rotation angle of the rotary stage based on a signal from the used head.

2. The optical foreign matter inspection device according to claim 1, wherein
the calculation control circuit stores rotation angle correction information for the first head and rotation angle correction information for the second head,
the rotation angle correction information for the first head is information having a characteristic which changes when an installation rotation angle of the first head and an eccentricity amount of the scale change,
the rotation angle correction information for the second head is information having a characteristic which changes when an installation rotation angle of the second head and an eccentric amount of the scale change, and
when specifying the rotation angle of the rotary stage, the calculation control circuit corrects the rotation angle of the rotary stage by using the rotation angle correction information for the first head when the head to be used is the first head, and by using the rotation angle correction information for the second head when the head to be used is the second head.

3. The optical foreign matter inspection device according to claim 2, wherein
there is a deviation between the center of rotation of the scale and a geometrical center of the scale, and
when the rotation center of the scale is set as the center of rotation of the rotation angle, the installation rotation angle of the first head and the installation rotation angle of the second head are different from each other.

4. The optical foreign matter inspection device according to claim 2, wherein
there is a deviation between a rotational speed determined based on a time interval at which the first head or the second head detects the graduations of the scale, and an actual rotational speed of the scale, and
when the rotation center of the scale is set as the center of rotation of the rotation angle, the installation rotation angle of the first head and the installation rotation angle of the second head are different from each other.

5. The optical foreign matter inspection device according to claim 1, wherein
the calculation control circuit
controls the motor so that the rotational speed of the rotary stage becomes a set value,
calculates an estimated value representing a true rotation angle of the rotary stage for a plurality of time points corresponding to one or more rotations of the rotary stage, based on a product of the set value of the rotational speed of the rotary stage and time,
specifies read values representing a rotation angle of the rotary stage for a plurality of time points corresponding to one or more rotations of the rotary stage, based on a signal output by the first head after detecting the graduations of the scale,
specifies read values representing a rotation angle of the rotary stage for a plurality of time points corresponding to one or more rotations of the rotary stage, based on a signal output by the second head after detecting the graduations of the scale,
compares the calculated estimated values of the rotation angles with the specified read values of the rotation angles by the first head to generate rotation angle correction information for the first head, and
compares the calculated estimated values of the rotation angles with the specified read values of the rotation angles by the second head to generate rotation angle correction information for the second head.

6. The optical foreign matter inspection device according to claim 1, wherein
the calculation control circuit
controls the motor to naturally decelerate after rotating the rotary stage,
calculates an estimated value of a rotational speed of the rotary stage and an estimated value of angular acceleration of the rotary stage for a plurality of time points corresponding to a plurality of rotations of the rotary stage, based on a detection time difference of an angle reference of the scale, and calculates an estimated value representing an actual rotation angle of the rotary stage for a plurality of time points corresponding to a plurality of rotations of the rotary stage, based on the calculated estimated value of the rotational speed and the calculated estimated value of the angular acceleration and an elapsed time,
specifies read values representing a rotation angle of the rotary stage for a plurality of time points corresponding to a plurality of rotations of the rotary stage, based on a signal from the first head,
specifies read values representing a rotation angle of the rotary stage for a plurality of time points corresponding to a plurality of rotations of the rotary stage, based on a signal from the second head,
compares the calculated estimated values of the rotation angles with the specified read values of the rotation angles by the first head to generate rotation angle correction information for the first head, and
compares the calculated estimated values of the rotation angles with the specified read values of the rotation angles by the second head to generate rotation angle correction information for the second head.

7. The optical foreign matter inspection device according to claim 1, wherein
when the rotation center of the scale is set as the center of rotation of the rotation angle, an installation rotation angle of the first head and an installation rotation angle of the second head are different from each other, and
the calculation control circuit phase-shifts rotation angle correction information for one of the first head and the second head by an installation angle difference between the first head and the second head to generate the rotation angle correction information for the other head.

8. The optical foreign matter inspection device according to claim 1, wherein
the calculation control circuit
executes predetermined processing to generate multiple times at intervals, rotation angle correction information for at least one of the first head or the second head, the rotation angle correction information being used for correction when specifying the rotation angle of the rotary stage based on a signal from the head,
determines a temporal change in correction intensity for the plurality of generated rotation angle correction information, and
outputs the determined temporary change in the correction intensity.

9. The optical foreign matter inspection device according to claim 1, wherein
the calculation control circuit
executes predetermined processing to generate rotation angle correction information for at least one of the first head or the second head, the rotation angle correction information being used for correction when specifying a rotation angle of the rotary stage based on a signal from the head, and
is connected to a management device via a server and transmits the generated rotation angle correction information to the management device, and
the management device outputs a plurality of rotation angle correction information received from a plurality of connected optical foreign matter inspection devices in a comparable manner.

10. The optical foreign matter inspection device according to claim 1, wherein
in the case in which the rotational speed of the rotary stage is within a common rotational speed range which is an overlapping portion of a rotational speed range supportable by the first head and a rotational speed range supportable by the second head, when the rotational speed is in the process of increasing over time, the calculation control circuit switches the head to be used from one of the first head and the second head to the other, and when the rotational speed is in the process of decreasing over time, the calculation control circuit switches the head to be used from the other of the first head and the second head to the one thereof.

11. An optical foreign matter inspection device which detects foreign matter on a surface of a sample, comprising:
a rotary stage on which the sample is placed;
a motor which rotates the rotary stage;
a base to which the motor is fixed;
an annular scale provided on the rotary stage;
a stage unit including a head which is installed on the base and which detects the graduations of the scale and outputs a signal;
a laser light source which irradiates laser light toward the surface of the sample;
an optical sensor which receives scattered or reflected light of the laser light from the surface of the sample and outputs a signal according to the intensity of the received light; and
a calculation control circuit which performs processing of controlling the motor and processing of specifying a position of the foreign matter on the sample based on the signal from the head and the signal from the optical sensor, wherein
the calculation control circuit stores rotation angle correction information for the head,
the rotation angle correction information for the head has a characteristic which changes when an installation rotation angle of the head changes, and
the calculation control circuit specifies a rotation angle of the rotary stage based on the signal from the head, and corrects the specified rotation angle using the rotation angle correction information for the head.

12. A program for use in an optical foreign matter inspection device including:
a rotary stage on which a sample is placed;
a motor which rotates the rotary stage;
a base to which the motor is fixed;
an annular scale provided on the rotary stage;
a first head and a second head which are installed on the base and which detect graduations of the scale and output a signal;
a laser light source which irradiates laser light toward a surface of the sample;
an optical sensor which receives scattered or reflected light from the surface of the sample and outputs a signal according to the intensity of the received light; and
a calculation control circuit including a processor, wherein
a rotational speed range of the rotary stage supportable by the first head and a rotational speed range of the rotary stage supportable by the second head are relatively different from each other so as to partially overlap, and
the program causes the processor to execute:
processing of controlling the motor,
processing of specifying a position of foreign matter on the sample based on the signal from the first head or the second head and the signal from the optical sensor,
processing of determining, based on a rotational speed of the rotary stage, either of the first head and the second head as a head to be used for specifying the rotation angle of the rotary stage, and
processing of determining a rotation angle of the rotary stage based on the signal from the head to be used.
